(19) United States
(12) Patent Application Publication
(10) Pub. No.: US 2025/0062156 A1
(43) Pub. Date: Feb. 20, 2025

(54) HEXAPOD-BASED PEDESTAL SYSTEMS FOR USE IN SEMICONDUCTOR PROCESSING OPERATIONS

(71) Applicant: Lam Research Corporation, Fremont, CA (US)

(72) Inventors: Jacob Lee Hiester, Newberg, OR (US); Jason Gordon Galginaitis, Portland, OR (US); Richard M. Blank, San Jose, CA (US)

(21) Appl. No.: 18/719,362

(22) PCT Filed: Dec. 12, 2022
(86) PCT No.: PCT/US2022/081389

§ 371 Date: Jun. 13, 2024

Related U.S. Application Data
(60) Provisional application No. 63/265,562, filed on Dec. 16, 2021.

(51) Int. Cl. H01L 21/687; H01L 21/68

(52) U.S. Cl. CPC H01L 21/68792; H01L 21/68; H01L 21/68707

(57) ABSTRACT

Semiconductor processing tools with hexapod-based pedestal systems are disclosed and described. Such hexapod pedestal systems may incorporate a hexapod mechanism with a stationary mount that is connected via six linear actuators with a movable mount. The movable mount may support a pedestal located within a semiconductor processing chamber. The hexapod mechanism may be controlled so as to allow the pedestal to shift laterally so as to center the pedestal on a wafer supported by a wafer handling robot, as well as to angularly align a wafer supported thereby with the underside of a showerhead and to allow a wafer supported thereby to be subjected to any of a variety of movements during wafer processing operations that may promote increased wafer uniformity.

### RELATED APPLICATION(S)

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Semiconductor processing tools typically include one or more pedestals that are used to support semiconductor wafers within a semiconductor processing chamber. Such a pedestal features a wafer support surface that is designed to have a wafer placed thereupon and to support that wafer during semiconductor processing operations within the semiconductor processing chamber. Pedestals may be equipped with any of a variety of ancillary systems, including, for example, vacuum chucks and/or electrostatic chucks (which may provide the wafer support surface of the pedestal), heating and/or cooling systems, electrodes used for radio-frequency energy transmission purposes, purge gas systems for protecting the undersides of wafers from process gases that are intended to only be applied to the upward-facing sides of the wafers, lift-pin mechanisms that may be used to raise wafers off of the wafer support surface (or lower wafers onto the wafer support surface), etc.

A pedestal is typically either fixed in location relative to the processing chamber in which it resides or configured to have only one or two degrees of freedom that it can be actively controlled to move along. For example, it is common for pedestals to be mounted on a vertical lift mechanism to allow such pedestals to be actively moved up and down during, for example, wafer placement operations and, in some instances, during processing operations. In some instances, pedestals may also or alternatively be configured to be able to be actively rotated about the vertical axis during or prior to wafer processing operations.

### SUMMARY

Details of one or more implementations of the subject matter described in this specification are set forth in the accompanying drawings and the description below. Other features, aspects, and advantages will become apparent from the description, the drawings, and the claims.

In some implementations, an apparatus may be provided that includes a pedestal configured to support a semiconductor wafer during wafer processing operations, a movable mount that supports the pedestal, a stationary mount, and six independently controllable linear actuators, each linear actuator having a first end pivotably connected with the stationary mount and a second end pivotably connected with the movable mount. The linear actuators may support the movable mount relative to the stationary mount, and the movable mount, the stationary mount, and the six independently controllable linear actuators may be arranged so as to provide a hexapod mechanism.

In some implementations, the linear actuators may be arranged in a trilaterally symmetric manner.

In some implementations, the six linear actuators may be grouped into three sets of two linear actuators, and the linear actuators in each pair of linear actuators may be arranged so as to have first ends that connect with the stationary mount at locations that are closer together than locations where the second sends thereof connect with the movable mount.

In some implementations, each first end of each linear actuator may be pivotably connected with the stationary mount by a corresponding spherical joint, universal joint, or biaxial flexure bearing, and each second end of each linear actuator may be pivotably connected with the movable mount by a corresponding spherical joint, universal joint, or biaxial flexure bearing.

In some implementations, each first end of each linear actuator may be pivotably connected with the stationary mount by a corresponding first biaxial flexure bearing.

In some implementations, each first biaxial flexure bearing may include an inner portion, an intermediate portion, an outer portion, two first torsion webs spanning between the inner portion and the intermediate portion, and two second torsion webs spanning between the intermediate portion and the outer portion. For each first biaxial flexure bearing in such implementations, the inner portion thereof may be interposed between the two first torsion webs thereof, and the intermediate portion thereof may be interposed between the two second torsion webs thereof.

In some implementations, for each first biaxial flexure bearing, the first torsion webs thereof may be thin, substantially planar structures aligned with a first reference plane of that first biaxial flexure bearing, the second torsion webs thereof may be thin, substantially planar structures aligned with a second reference plane of that first biaxial flexure bearing, and the first and second reference planes thereof may be perpendicular to one another.

In some implementations, the intermediate portion may include two opposing first segments arranged on opposite sides of the inner portion and first torsion webs and spaced apart from the inner portion such that gaps exist between the first segments and the inner portion, the intermediate portion may further include two opposing second segments arranged on opposite sides of the inner portion and spaced apart from the inner portion such that gaps exist between the second segments and the inner portion, each second segment may be connected with the inner portion by a corresponding one of the second torsion webs, the intermediate portion may further include four bridging segments, each bridging segment extending between a different pair of the first and second segments, and the second segments may be further from a center axis of the inner portion than the first segments.

In some implementations, the first segments may be curved segments having convex surfaces facing towards the inner portion.

In some implementations, the first segments may be arcuate segments that are concentric with the inner portion.

In some implementations, the bridging segments may be linear segments.

In some implementations, the bridging segments may be parallel to one another.

In some implementations, the second segments may be located entirely outside of a reference circle that circumscribes the first segments.

In some implementations, the distances between the inner portion and the second segments may be at least 1.5 times the distances between the inner portion and the first segments.

In some implementations, the distances between the inner portion and the second segments may be at least twice as large as the distances between the inner portion and the first segments.

In some implementations, for each first biaxial flexure bearing, a first reference axis defined by the intersection of the first and second reference planes may be parallel to an extension axis of the linear actuator connected to that first biaxial flexure bearing.

In some implementations, each second end of each linear actuator may be pivotably connected with the movable mount by a corresponding second biaxial flexure bearing.

In some implementations, each second biaxial flexure bearing may includes an inner portion, an intermediate portion, an outer portion, two first torsion webs spanning between the inner portion and the intermediate portion, and two second torsion webs spanning between the intermediate portion and the outer portion. In such implementations, for each first biaxial flexure bearing, the inner portion thereof may be interposed between the two first torsion webs thereof, and the intermediate portion thereof may be interposed between the two second torsion webs thereof.

In some implementations, for each second biaxial flexure bearing, the first torsion webs thereof may be thin, substantially planar structures aligned with a first reference plane of that second biaxial flexure bearing, the second torsion webs thereof may be thin, substantially planar structures aligned with a second reference plane of that second biaxial flexure bearing, and the first and second reference planes thereof may be perpendicular to one another.

In some implementations, for each second biaxial flexure bearing, the first and second reference planes may intersect along a center axis thereof, and the center axis thereof may be parallel to an extension axis of the linear actuator connected thereto.

In some implementations, the apparatus may further include a semiconductor processing chamber and a showerhead. In such implementations, the wafer support surface of the pedestal may be located within the semiconductor processing chamber, at least a portion of the showerhead may be located within the semiconductor processing chamber, and the stationary mount may be fixed with respect to the semiconductor processing chamber.

In some implementations, the apparatus may further include a controller operatively connected with the six linear actuators and configured to control the linear actuators so as to cause the movable mount to perform, relative to the stationary mount, one or more of: a) translation of the movable mount along an axis that is perpendicular to the wafer support surface of the pedestal, b) rotation of the movable mount about a rotational axis that passes through a target location of the pedestal on which a wafer is to be centered and is perpendicular to the wafer support surface, c) translation of the movable mount along a path so as to orbit an axis that is perpendicular to an underside of the showerhead that faces towards the pedestal and that intersects with a target location of the showerhead, d) tilting of the movable mount such that the wafer support surface of the pedestal is oriented at a non-zero acute angle to the underside of the showerhead, or e) tilting of the movable mount such that the wafer support surface of the pedestal is oriented at a non-zero acute angle to the underside of the showerhead and such that a maximum acute angle that is formed between the underside of the showerhead and the wafer support surface is defined in a plane that is periodically or continuously caused to change azimuthal direction relative to the pedestal and about an axis that is perpendicular to the underside of the showerhead.

In some implementations, the controller may be further configured to control the linear actuators so as to cause the movable mount to perform two or more of (a) through (e) at least partially simultaneously while the pedestal is supporting a wafer placed thereupon.

In some implementations, the controller may be further configured to control the linear actuators so as to cause the movable mount to perform two or more of (a) through (e) at least partially sequentially while the pedestal is supporting a wafer placed thereupon.

In some implementations, the apparatus may further include a wafer handling robot configured to extend an end effector thereof into the semiconductor processing chamber, and an active wafer centering system configured to determine a location of a center of a wafer transported by the end effector relative to the semiconductor processing chamber. In such implementations, the controller may be further configured to i) obtain the location of the center of the wafer as determined by the active wafer centering system, ii) control the linear actuators so as to cause the target location of the pedestal to be positioned at a location centered beneath the center of the wafer based on the location of the center of the wafer as determined by the active wafer centering system, and iii) cause the wafer to be transferred to the pedestal after (ii). In some implementations, the pedestal may include a plurality of lift pins and the apparatus may include a lift pin actuation mechanism that is configured to move the lift pins between an extended state in which the lift pins protrude from the wafer support surface of the pedestal and a retracted state in which the lift pins do not protrude from the wafer support surface. In such implementations, the controller may be configured to perform (iii) by causing the lift pin actuation mechanism to cause the lift pins to move into the extended state so as to come into contact with the wafer, causing the wafer handling robot to retract the end effector from the space between the wafer and the wafer support surface, and causing the lift pin actuation mechanism to cause the lift pins to move into the retracted state, thereby placing the wafer on the wafer support surface. In some other or additional such implementations, the controller may be further configured to, after (iii), control the linear actuators so as to cause the movable mount to move to an orientation in which the wafer support surface is at a predetermined angle relative to the underside of the showerhead. In some implementations, the predetermined angle is 0°. In some other implementations, the predetermined angle may be a non-zero acute angle.

In addition to the above-listed implementations, other implementations evident from the discussion below and the Figures are to be understood to also fall within the scope of this disclosure.

### BRIEF DESCRIPTION OF THE DRAWINGS

Reference to the following Figures is made in the discussion below; the Figures are not intended to be limiting in scope and are simply provided to facilitate the discussion below.

FIG. 1 depicts an example hexapod-based pedestal system in a semiconductor processing chamber.

FIG. 2 depicts an isometric view of the example hexapod-based pedestal system of FIG. 1.

FIG. 3 depicts a side view of the example hexapod-based pedestal system of FIG. 1.

FIG. 4 depicts an isometric exploded view of the example hexapod-based pedestal system of FIG. 1.

FIG. 5 depicts a plan view of an example biaxial flexure bearing.

FIG. 6 is an isometric view of two example biaxial flexure bearings.

FIGS. 7 and 8 depict isometric cutaway views of one of the example biaxial flexure bearings of FIG. 6.

FIGS. 9 and 10 depict side views of the biaxial flexure bearing of FIGS. 7 and 8.

FIG. 11 depicts a dimetric view of the example hexapod-based pedestal system similar to that of FIG. 1 but using biaxial flexure bearings similar to those shown in FIGS. 7-8.

FIG. 12 depicts a dimetric exploded view of the example hexapod-based pedestal system of FIG. 11.

FIGS. 13 and 14 depict views of an example quad-station module.

FIG. 15 depicts a flow diagram for a technique for loading a wafer onto a pedestal of a hexapod-based pedestal system.

FIG. 16 depicts a flow diagram for a technique for moving a wafer during processing operations using a hexapod-based pedestal system.

FIG. 17 shows top, front, side, and isometric views of a hexapod-based pedestal system with the pedestal in an elevated position.

FIG. 18 shows top, front, side, and isometric views of a hexapod-based pedestal system with the pedestal in a lowered position.

FIG. 19 shows top, front, side, and isometric views of a hexapod-based pedestal system with the pedestal in lift-pin extended position.

FIG. 20 shows, from left to right, top, front, side, and isometric views of a hexapod-based pedestal system with the pedestal in three different rotation positions.

FIG. 21 shows, from top to bottom, top, front, side, and isometric views of a hexapod-based pedestal system with the pedestal in different orbital positions.

FIG. 22 shows, from left to right, top, front, side, and isometric views of a hexapod-based pedestal system with the pedestal in a first tilted position.

FIG. 23 shows, from left to right, top, front, side, and isometric views of the hexapod-based pedestal system of FIG. 22 with the pedestal in a second tilted position.

FIG. 24 depicts a flow diagram for a technique for calibrating a semiconductor processing tool having a hexapod-based pedestal system.

FIGS. 25 through 36 depict diagrams of portions of a semiconductor processing tool during various stages of the technique of FIG. 24.

The above-described Figures are provided to facilitate understanding of the concepts discussed in this disclosure, and are intended to be illustrative of some implementations that fall within the scope of this disclosure, but are not intended to be limiting-implementations consistent with this disclosure and which are not depicted in the Figures are still considered to be within the scope of this disclosure.

### DETAILED DESCRIPTION

Disclosed herein are new types of semiconductor wafer support and positioning systems for use in semiconductor processing chambers. Such systems generally feature a hexapod mechanism that has a stationary mount and a movable mount; six independently controllable linear actuators connect the stationary mount with the movable mount in a configuration generally referred to as a “Stewart platform.” The stationary mount of the hexapod mechanism is fixedly mounted with respect to a semiconductor processing chamber, while the movable mount of the hexapod supports a pedestal that is used to support a semiconductor wafer within the semiconductor processing chamber.

Stewart platforms are typically used in applications where six degrees of freedom are required over a relatively large range of motion, such as flight simulators, radio telescopes, spacecraft docking systems, etc. Such Stewart platform systems may, for example, frequently be designed to be able to tilt their movable mounts by as much as 45° to 60° of tilt in any direction and are often able to translate their movable mounts in all directions by significant distances.

In a semiconductor processing chamber, the pedestal that is used to support a semiconductor wafer within the semiconductor processing chamber is typically fixed in place relative to the semiconductor processing chamber or is configured to translate vertically and/or, in some rare instances, rotate about a vertical axis. While some semiconductor processing chambers may have mechanisms, e.g., set screws, alignment shims, etc., that allow for a pedestal's horizontal location and/or pitch or roll orientation to be fine-tuned prior to use, such mechanisms are passive mechanical systems that are designed to be adjusted by hand during initial tuning and set-up procedures and then locked into place so as to fix the pedestal in a desired horizontal location and/or angular orientation. The pedestal then remains in that horizontal location and/or angular orientation unless such mechanisms are later re-adjusted or spontaneously drift, but may, if equipped with actuators providing for such movement, still be actively controlled to move vertically and/or rotationally about the vertical axis. This approach is typically followed since it offers only limited degrees of freedom that can serve as potential sources for positioning errors, thereby resulting in typically greater confidence as to the position of wafers supported by such pedestals at any given time.

In contrast, the wafer support and positioning systems discussed herein allow for target locations, e.g., the centers (or locations on the pedestals that are intended to align with the center of semiconductor wafers supported thereby), of the pedestals supported thereby—and an orientation of the pedestals supported thereby—to be actively and controllably repositioned between any number of locations and orientations within a three-dimensional envelope or zone. Thus, whereas existing pedestal systems offer either no ability to be actively adjusted or only a limited ability to be actively adjusted, e.g., having only one or two degrees of freedom, the wafer support and positioning systems discussed herein, due to their use of a hexapod mechanism, have at least five, and, in some cases, six, degrees of freedom that dramatically increases the capabilities of the pedestals supported thereby.

For example, a wafer support and positioning system that incorporates a hexapod mechanism such as is discussed herein may allow for dynamic adjustment of the position and orientation of the pedestal supported thereby relative to, for example, a showerhead of the processing chamber with which it is used. For example, it is typically desired to align the wafer support surface of the pedestal with the underside of the showerhead such that the wafer support surface of the pedestal is parallel to the underside of the showerhead (or to a nominal reference plane that is defined by a non-planar underside surface of the showerhead). Such alignment is typically done manually, e.g., using set screws or other fine-tuning mechanisms, during initial equipment set-up and the adjustment mechanism used to perform such alignment then locked in place. A hexapod-based pedestal system as discussed herein, however, may simply be controlled so as to actively tilt the pedestal supported thereby so as to align the wafer support surface of the pedestal with the surface on the underside of the showerhead.

A hexapod-based pedestal system as discussed herein may also be controlled such that it repositions during wafer placement operations. In a traditional pedestal system, wafers placed on the pedestal typically vary slightly in terms of where their wafer centers are located relative to the end effectors that are used to place such wafers on such a pedestal. Without correction, this would result in wafers being sequentially placed at different locations on the receiving pedestal, which would result in each wafer experiencing potentially varying degrees of processing non-uniformity. It is thus common practice for a semiconductor processing chamber to be equipped with an active wafer centering (AWC) system. An AWC system uses optical sensors to detect at least three points along the wafer edge as the wafer is moved into the semiconductor processing chamber by a wafer handling robot. Such edge/point locations may then be used to determine the center location of the wafer relative to the end effector of the wafer handling robot. In typical practice, the AWC system is trained using a calibration wafer that is usually centered on the pedestal using an alignment fixture or other device and is then removed from the pedestal using a wafer handling robot. The wafer handling robot is then caused to follow a predetermined path that causes the calibration wafer to pass through the AWC system optical sensors and a determination is made as to the center location of the calibration wafer relative to the end effector of the wafer handling robot. This center location, as determined by the AWC system, may be used as the “reference” location that is then used to determine by how much future wafers handled by the wafer handling robot are “off center” from the reference location. Thus, for example, a future wafer-to-be-processed may be placed on the end effector of the wafer handling robot, and the wafer handling robot then caused to follow the same predetermined path such that the wafer-to-be-processed passes through the AWC system in the same manner as the calibration wafer. The center location of the wafer-to-be-processed is determined in the same manner as was used to determine the center location of the calibration wafer. If the center location of the wafer-to-be-processed as measured by the AWC system is offset from the center location of the calibration wafer as measured by the AWC system by a distance that is large enough that correction is required, then the wafer handling robot may be controlled to adjust its movements within the chamber so as to offset the placement of the wafer on the pedestal by an amount that counteracts the offset that was measured between the calibration wafer center and the center of the wafer-to-be-processed. Thus, for example, if the center of the wafer-to-be-processed was offset from the center of the calibration wafer in an XY coordinate system by (−1 mm, 0.5 mm), the wafer handling robot would be controlled so as to move the end effector thereof to the XY location it was in when the calibration wafer was placed thereupon, but adjusted to cancel out the (−1 mm, 0.5 mm) offset. For example, the end effector would be moved to the X coordinate of the XY location plus 1 mm and the Y coordinate of the XY location minus 0.5 mm.

Such an approach works well in some situations, but can be problematic in semiconductor processing tools in which there are multiple processing stations, each with its own pedestal, and in which wafers may be placed on some such pedestals using systems that do not have the ability to adjust the placement location of the wafers prior to placement. For example, in semiconductor processing tools with four stations, a rotational indexer may be used to move wafers between stations, and a wafer handling robot may only be able to directly place wafers on two of the four stations. The indexer may then be used to move wafers placed on a pedestal by a wafer handling robot to one of the pedestals that is not accessible to the wafer handling robot. However, indexers are typically only capable of rotational movement, and are thus typically very limited in their ability to correct for wafer center offsets.

By using a hexapod-based pedestal system such as is described herein, the pedestal can be made to be an active participant in wafer centering operations. For example, in the techniques discussed above, the pedestal remains fixed in the XY plane and all movement needed to align the center of the wafer-to-be-processed with a target location on the pedestal is performed by the wafer handling robot (or, potentially, by a rotational indexer). However, in a hexapod-based pedestal system, the pedestal can instead be caused to move so as to center the target location on the pedestal under the center of the wafer. Thus, for example, the wafer handling robot can simply be controlled so as to return to the same position it was in when the calibration wafer was placed on the end effector thereof. The hexapod-based pedestal system can similarly be controlled so as to also return to the same position and orientation it was in when the calibration wafer was placed on the end effector, but adjusted in the XY direction(s) so as to compensate for any offset between the center of the wafer-to-be-processed and the center of the calibration wafer, as determined by the AWC system. After the wafer-to-be-processed is placed on the pedestal, the hexapod-based pedestal system may be controlled to cause the pedestal to move to, for example, a position that orients the wafer support surface of the pedestal so as to be parallel to the underside surface of the showerhead.

It will be appreciated that such a hexapod-based pedestal system may allow for wafer centering operations to be performed independently and simultaneously at each station of a multi-station chamber that is equipped with such a system, even when the wafers being placed on the pedestals thereof are supported by a single, common structure (such as an indexer or an end effector that supports multiple wafers simultaneously over different pedestals). In some instances, this may allow for wafer centering operations to be performed that could not otherwise be achieved. In other or additional instances, this may allow for wafer centering operations to be performed in parallel which would otherwise need to be performed sequentially, thereby reducing the amount of time needed to complete wafer centering operations and increasing throughput.

Hexapod-based pedestal systems also offer a uniquely flexible positioning solution that may also be actively controlled during semiconductor processing operations in order to provide potentially beneficial effects. For example, a hexapod-based pedestal system may be controlled so as to cause the pedestal thereof to undergo particular movement patterns during wafer processing operations. In one such example, a hexapod-based pedestal system may be caused to simply translate the pedestal along the “yaw” axis of the movable mount of the hexapod mechanism that supports the pedestal, thereby causing the gap between the wafer supported thereby and the showerhead to increase or decrease. Such gap tuning may be used to influence how the wafer is processed. In another example, the hexapod mechanism may be controlled so as to introduce a deliberate, although small, angular misalignment between the underside of the showerhead and the wafer support surface of the pedestal. Such an angular misalignment may, in some circumstances, provide a beneficial effect. In yet another example, the hexapod mechanism may be controlled so as to cause the pedestal to “orbit” around a center point, e.g., to cause the pedestal to undergo XY translation so as to follow a circular path. Such orbital movement may, for example, help reduce localized non-uniformities that may arise in the wafer by causing the effects that produce the non-uniformities to be spread out over a wider area, thereby decreasing the peak magnitudes of the non-uniformity.

These and other techniques and benefits that are provided through the use of hexapod-based pedestal systems are discussed in more detail below with respect to the Figures.

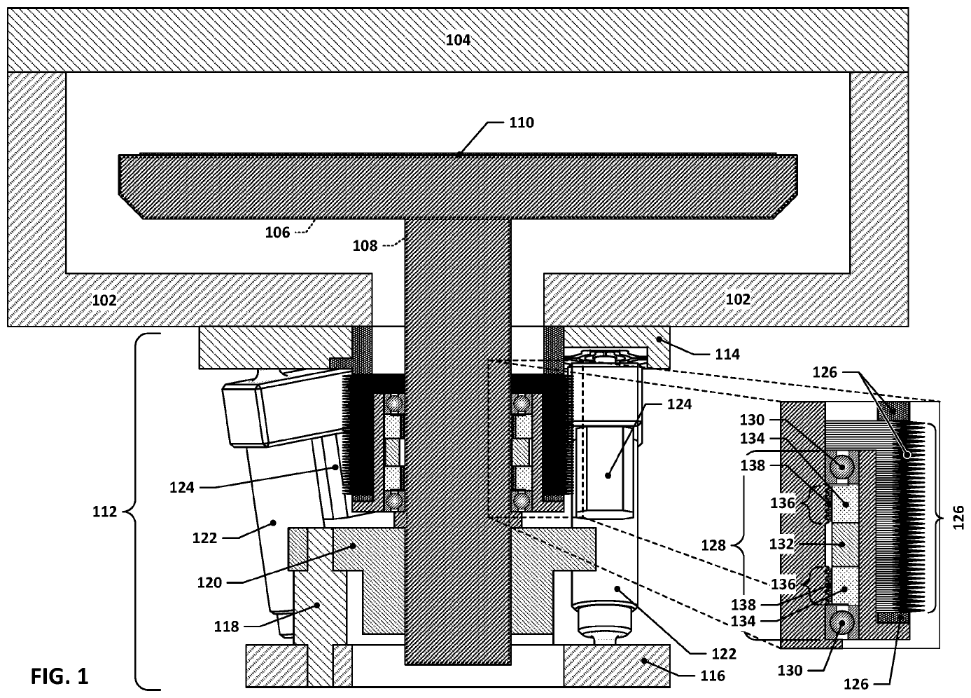

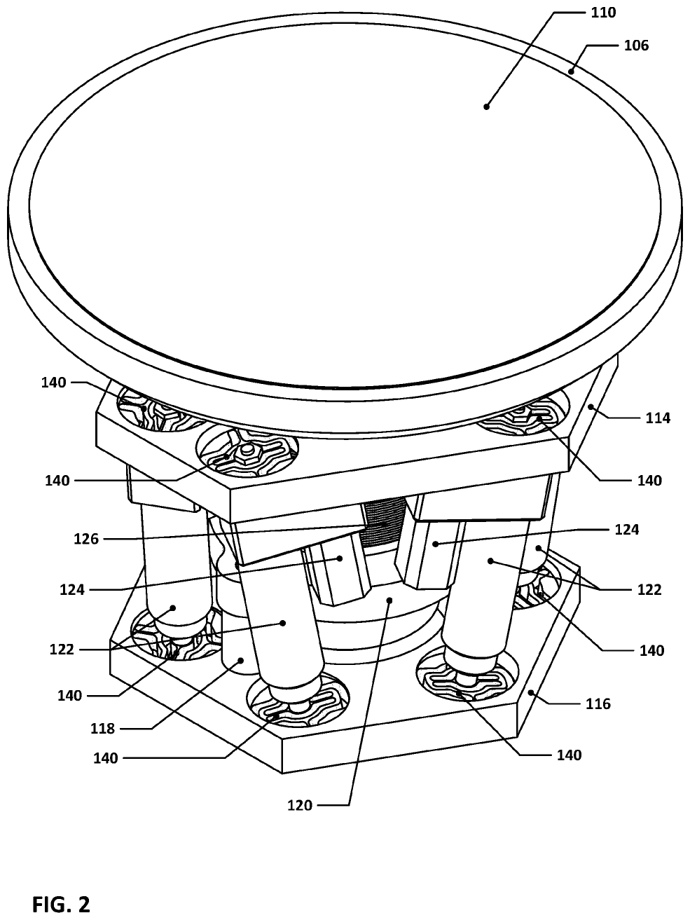

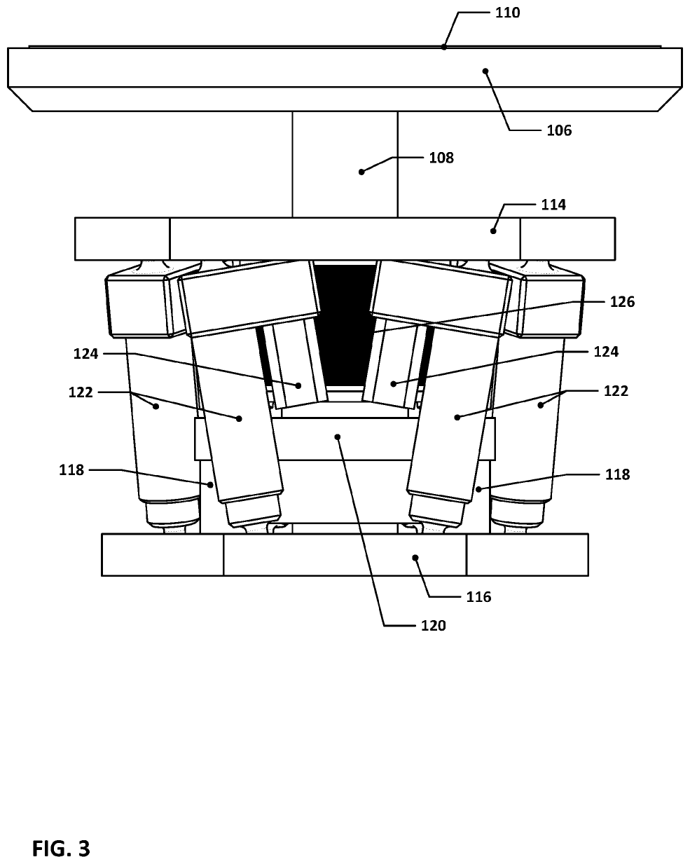

FIG. 1 depicts an example semiconductor processing tool having a semiconductor processing chamber with a hexapod pedestal system. FIGS. 2-4 depict the hexapod pedestal system, with the semiconductor processing chamber omitted, in isometric, side, and isometric exploded views.

As seen in FIG. 1, semiconductor processing tool 100 is depicted that includes a semiconductor processing chamber 102 that is capped by a lid 104. The lid 104 may, for example, be a flush-mount showerhead (not shown) that includes a plurality of gas distribution ports on the underside thereof that are fluidically connected with one or more gas distribution plenums within the showerhead and which may be used to flow processing gases across a wafer 110 that is supported on a pedestal 106 during semiconductor wafer processing operations. In some implementations, the semiconductor processing chamber may have a chandelier-type showerhead (not shown) that is suspended beneath the lid 104 by a stem that passes through the lid 104.

The pedestal 106 may have a support column 108 that may extend through the floor of the semiconductor processing chamber 102. It will be understood that the support column 108, while shown as a contiguous part of the pedestal 106, can be a separate structure from the pedestal 106 that is then fixedly connected with the pedestal 106 using fasteners or other attachment devices. It is also to be understood that while the pedestal 106 and the support column 108 are both shown as relatively simple monolithic parts, in actual practice, they may be complex multi-part assemblies. For example, the support column 108 may be hollow and/or have one or more passages that extend along its length in order to allow cables, gas flow lines, coolant flow lines, etc., to potentially be routed therethrough. The pedestal 106, in some embodiments, may include internal features such as thermal breaks, coolant flow paths, heater elements, electrodes, gas flow paths, pass-throughs for lift-pins, etc. It will be understood that the hexapod-based pedestal mechanisms discussed herein may generally be used with any suitable pedestal type, including pedestals 106 including any one or more of the systems described above (or other systems not explicitly listed above).

Also depicted in FIG. 1 is an example hexapod mechanism 112, which includes a stationary mount 114 that is bolted to or otherwise fixedly connected with the semiconductor processing chamber 102. The hexapod mechanism 112 also includes a movable mount 116 that is connected with the stationary mount 114 by six linear actuators 122. Each linear actuator 122 is able to be driven independently by a corresponding motor 124. It will be understood that while the depicted linear actuators are all of similar design, length, diameter, and throw, some embodiments may feature linear actuators in which two or more of the linear actuators are different in design or construction, e.g., having different lengths (either maximum or minimum), diameters, throw, etc. The linear actuators are all independently controllable so as to be able to be extended or retracted to different lengths independently of the extension or retraction of the other linear actuators (although generally not in a way that is kinematically incompatible with the overall assembly kinematics). The linear actuators may, as shown, be arranged in a radially symmetric manner, e.g., a trilaterally symmetric manner (e.g., having 3-fold radial symmetry), although in some other implementations, the linear actuators may be arranged in a non-radially symmetric manner.

It will also be recognized that while the depicted linear actuators 112 have drive motors 124 that are part of the portions of the linear actuators 112 that are mounted to the stationary mount 114, but other implementations may feature linear actuators 112 in which the motors 124 are part of the portions of the linear actuators 112 that are mounted to the movable mount 114 (or which may feature a mix of such linear actuators, e.g., some linear actuators with motors that are part of the portions of the linear actuators that are mounted to the movable mounts and some linear actuators with motors that are part of the portions of the linear actuators that are mounted to the stationary mounts).

The hexapod mechanism 112 generally has a configuration, shown in more detail in FIGS. 2-4, in which the six linear actuators 122 are grouped into three pairs, with the three pairs of linear actuators 122 being arranged in a circular array about a common center axis. Each pair of linear actuators 122 may be arranged such that the linear actuators 122 in that pair of linear actuators 122 are arranged to extend or retract the movable portions thereof along translation axes that are—at least when the linear actuators 122 are at similar degrees of extension—at oblique angles to a corresponding reference plane that is coincident with the common center axis and located between the linear actuators 122 of that pair of linear actuators 122. Thus, the spacing between the locations where each pair of adjacent linear actuators 122 connect with the stationary mount 114 or the movable mount 116 will be different from the spacing between the locations where that pair of adjacent linear actuators 122 connect with the other of the stationary mount 114 and the movable mount 116.

In hexapod systems, each linear actuator that is used is configured so as to have at least five degrees of freedom that are unconstrained. This can be accomplished by pivotably connecting one end of each linear actuator with one of the stationary mount or the movable mount using a spherical joint (such as a ball joint) to provide three of the five degrees of freedom and pivotably connecting the other end of each linear actuator with the other of the stationary mount or the movable mount using a universal joint to provide the other two degrees of freedom (or, alternatively, with another spherical joint to provide six degrees of freedom). The use of spherical and universal joints allows for large angular displacements of the linear actuators relative to one or both of the stationary mount and the movable mount in such hexapod systems, providing for a wide range of angular motion. For clarity, the term “pivotably connected,” as used herein with respect to two components refers to a connection that allows one component to rotate relative to another component about one or more axes.

In some contexts of hexapod mechanisms for use in the hexapod-based pedestal systems discussed herein, the linear or angular displacements that the hexapod mechanism may need to provide may be much less, at least in some directions or about some axes, than in others. For example, a hexapod mechanism that is used in a hexapod-based pedestal system may be designed to provide for a significantly larger vertical displacement range for the movable mount as compared with the horizontal displacement range, e.g., ±25 mm in the vertical direction as compared with, for example, ±1.5 mm in horizontal directions. This is because the vertical movement of the pedestal using the hexapod mechanism may be used to replace gross movement of the pedestal that is used to accommodate wafer placement operations or to bring the pedestal closer to the showerhead during processing operations-which may involve needing to move the pedestal by several centimeters. In contrast, the horizontal movement of the pedestal using the hexapod system may be used, in many cases, simply to fine-tune the location of the pedestal relative to the wafer center or to a target location (e.g., the center) of the showerhead. Such corrective movements are typically quite small, e.g., on the order of less than a millimeter or two. Of course, if larger amounts of horizontal movement are desired, e.g., to perform a larger-diameter orbital motion as described above, then the maximum amount of horizontal displacement needed to support such movements may govern the maximum amount of horizontal displacement that the hexapod mechanism will be asked to provide.

Similarly, the angular displacements that the movable mount of a hexapod may be subjected to during normal use in the context of a hexapod-based pedestal system may be quite small, e.g., on the order of ±0.2° about the pitch and/or roll axes. Such angular displacements are typically sufficient to allow for any non-parallelism between the wafer support surface of the pedestal and the underside surface of the showerhead to be adjusted out and eliminated through tilting of the pedestal. The amount of rotation of the movable mount about the yaw axis that such hexapod mechanisms must be able to provide may, in some cases, be nonexistent (for example, if no such rotation of the pedestal is desired). In other implementations, however, the hexapod mechanism that is used may be designed to provide a significant amount of such rotational movement about the yaw axis, e.g., ±10°, ±20°, or even as much as ±30°.

At the same time, hexapod mechanisms used for hexapod-based pedestal systems may be required to provide positional and rotational accuracy with respect to the position and orientation of the pedestal and movable mount that is in the range of, for example, ±25 μm and ±0.02°.

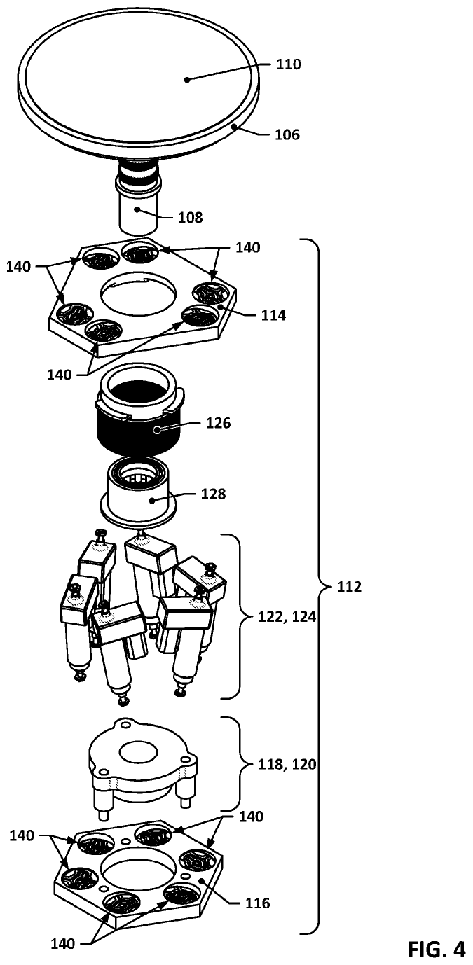

In view of the above, some implementations of hexapod-based pedestal systems may, as shown in FIGS. 2 and 4, avoid the use of spherical and/or universal joints and may instead utilize biaxial flexure bearings 140 that are used to pivotably connect one or both ends of each linear actuator 122 with the movable mount 116 or the stationary mount 114. Each biaxial flexure bearing 140 provides two degrees of rotational freedom, acting, in effect, like a universal joint with a very limited motion range. If two biaxial flexure bearings 140 are used with each linear actuator 122, then the fifth degree of freedom may be provided through the use of a linear actuator 122 in which one portion thereof is not only able to extend or retract along an extension axis relative to the other portion thereof, but is also able to freely rotate (at least somewhat) relative to the other portion thereof about the extension axis.

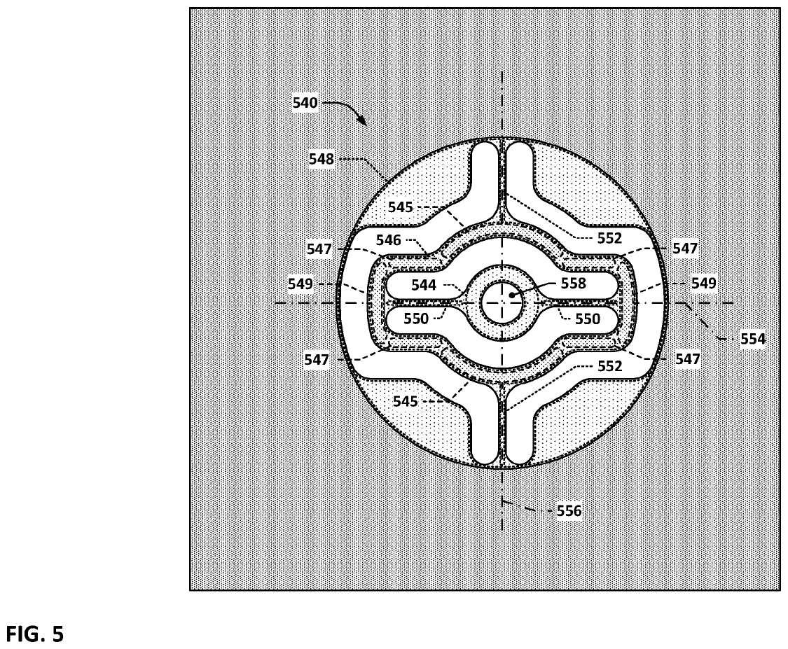

FIG. 5 depicts a detail view of an example biaxial flexure bearing similar to those used in the hexapod-based pedestal system of FIGS. 1 through 4. As shown, a biaxial flexure bearing 540 is shown that is a monolithic component that is machined or formed from a larger piece of material; the biaxial flexure bearing 540 may have a generally constant cross-section through its thickness (into the page). The biaxial flexure bearing 540 includes three separate portions—an inner portion 544 that has a mount hole 558 through it, an intermediate portion 546 that extends around the inner portion 544, and an outer portion 548 that extends around the intermediate portion 546. The inner portion 544 may be separated from the intermediate portion 546 by a gap that extends around nearly the entire outer perimeter of the inner portion 544 except for two locations where first torsion webs 550 span between the inner portion 544 and the intermediate portion 546. The first torsion webs 550 may be thin webs of material that are located on opposite sides of the inner portion 544 and that support the inner portion 544 relative to the intermediate portion 546. The first torsion webs 550 may have thicknesses in a direction normal to the sectioning plane of FIG. 5 that are significantly larger than the thicknesses of the first torsion webs 550 along the vertical axis with respect to the orientation of FIG. 5. For example, the thickness of the first torsion webs 550 in the in-page direction may be on the order of a centimeter, e.g., 8, 9, 10, 11, or 12 millimeters, while the thickness of the first torsion webs 550 in the vertical direction of FIG. 5 may be on the order of a millimeter or less, e.g., less than about 0.9 mm, 0.8 mm, 0.7 mm, 0.6 mm, or 0.5 mm. The first torsion webs 550 may, for example, have lengths that are of a similar order of magnitude to the in-page thickness, e.g., on the order of a centimeter or less, e.g., 5, 6, 7, 8, or 9 mm, for example. The first torsion webs 550 are much stiffer in bending about axes that are parallel to the sectioning plane of FIG. 5 and also perpendicular to a first reference plane 554 than they are in torsion about a center axis that is parallel to both the first reference plane 554 and the sectioning plane of FIG. 5 and which passes through the middle of each first torsion web 550. The first reference plane 554 may generally correspond to the mid-planes of the first torsion webs 550 along the thinnest dimensions thereof, e.g., the first torsion webs 550 may be substantially planar structures that are aligned with the first reference plane 554. Thus, the first torsion webs 550 may allow the inner portion 544 to twist relatively easily (at least, for a limited range of rotation) relative to the intermediate portion 546 and about an axis that is parallel to the first reference plane 554 and the sectioning plane of FIG. 5 while generally constraining the inner portion 544 from otherwise moving relative to the intermediate portion 546.

Similarly, the intermediate portion 546 may be separated from the outer portion 548 by a gap that extends around nearly the entire outer perimeter of the intermediate portion 546 except for two locations where second torsion webs 552 span between the intermediate portion 546 and the outer portion 548. The second torsion webs 552 may be similar to the first torsion webs 550 in terms of size and shape and are located on opposite sides of the intermediate portion 546. The second torsion webs 552 support the intermediate portion 546 relative to the outer portion 548.

The second torsion webs 552, similar to the first torsion webs 550, are much stiffer in bending about axes that are parallel to the sectioning plane of FIG. 5 and also perpendicular to a second reference plane 556 than they are in torsion about a center axis that is parallel to both the second reference plane 556 and the sectioning plane of FIG. 5 and which passes through the middle of each second torsion web 552. The second reference plane 556 may generally correspond to the mid-planes of the second torsion webs 552 along the thinnest dimensions thereof, e.g., the second torsion webs 552 may be substantially planar structures that are aligned with the second reference plane 556. Thus, the second torsion webs 552 may allow the intermediate portion 546 to twist relatively easily (at least, for a limited range of rotation) relative to the outer portion 548 and about an axis that is parallel to the second reference plane 556 and the sectioning plane of FIG. 5 while generally constraining the intermediate portion 546 from otherwise moving relative to the outer portion 548.

Biaxial flexure bearings such as the biaxial flexure bearing 540 allow a component, e.g., an actuator shaft or body, that is fixedly mounted with respect to the mount hole 558 and the inner portion 544 to be subjected to a limited range of angular displacements in any direction away from the nominal centerline of the mount hole 558; the nominal centerline of the mount hole 558 may, for example, be coincident with both the first reference plane 554 and second reference plane 556.

Such biaxial flexure bearings 140 (or 540) are typically more precise than spherical bearings or universal joints since they include no sliding or rolling interfaces, thereby requiring no clearance gaps to accommodate such relatively moving components and thus zero backlash or slop. Moreover, the biaxial flexure bearings 140 may be able to be packaged in a smaller volume or envelope as compared with equivalent spherical bearings or universal joints. The biaxial flexure bearings 140 may also be machined directly into the movable mount 116 and the stationary mount 114 and may therefore reduce the number of components that must be assembled and may be, in such cases, cheaper to manufacture than equivalent spherical bearings or universal joints.

For example, the geometry of the biaxial flexure bearing depicted in FIG. 5 features an intermediate portion 546 that has first segments 545 that are located on opposing sides of the inner portion 544 and at a first distance from a center axis of the inner portion 544 and second segments 549 that are located on opposing sides of the inner portion 544 and at a second distance from the center axis of the inner portion 544. The second segments 549 are located a further distance from the center axis than are the first segments 545 and are connected with the inner portion by way of the first torsion webs 550. At the same time, the intermediate portion 546 also has bridging segments 547 that each connect a different first and second segment pair. In the depicted example, the bridging segments 547 are all linear and parallel to one another (and the bridging segments 547 that are on either side of the first reference plane 554 are generally co-linear with one another). However, it will be understood that other configurations may feature non-parallel and/or non-linear bridging segments 547.

The first segments 545 in the example of FIG. 5 are curved or arcuate in shape, although other biaxial flexure bearings may feature first segments of a different shape. However, it is to be understood that the general geometry of the intermediate portion 546 as shown in FIG. 5, e.g., generally elongate in nature (having a dimension in a direction perpendicular to the first reference plane that is less or substantially less, than the dimension it has in a direction perpendicular to the second reference plane), permits the depicted biaxial flexure bearing 540 to be packaged in a much more space-efficient manner than may be achieved using other geometries.

For example, this allows the first and second flexure webs 550 and 552 to each have radial lengths (with respect to the center axis of the flexure bearing 540) that are approximately half of the distance between the center of the flexure bearing 540 and the outer diameter of the outer portion 548 while, at the same time, allowing for the thicknesses of the intermediate portion 546 structure and the inner portion 544 structure, the radius of the mount hole 558, and the gap between the inner portion 544 and the intermediate portion 546 to be accommodated.

It will be appreciated that intermediate portions 546 with elongate aspect ratios allow the (radius of mount hole 558+first flexure web 550 radial length+second flexure web 552 radial length+radial width of intermediate portion 546) to exceed the radius of the outer portion 548 (or, perhaps more correctly, the radius of a circle that circumscribes the second flexure webs 552). This allows the flexure webs to be provided with greater radial lengths (thus increasing the amount of flexure they can withstand without failure) than might otherwise be able to be packaged within an outer portion 548 having a given diameter. For example, if the intermediate portion 546 were to have a non-elongate aspect ratio, e.g., 1:1, then the (radius of mount hole 558+first flexure web 550 radial length+second flexure web 552 radial length+radial width of intermediate portion 546) would be forced to equal the radius of the outer portion 548, thereby limiting the length of the first and second flexure webs 550 and 552 (and consequently limiting the amount of flexure that the biaxial flexure bearing 540 can provide). In contrast, if the biaxial flexure bearing 540 of FIG. 5 is taken as being drawn to scale, e.g., with the second segments 547 located entirely outside of a reference circle that circumscribes the first segments 545, the first and second flexure webs 550 and 552 may be 50% or more longer in radial length (and a correspondingly larger amount of angular deflection capability) than may be achieved for the same size biaxial flexure bearing with an intermediate portion having a 1:1 aspect ratio. In some implementations, the distances between the inner portion and the second segments may be at least 1.5 or at least 2 times the distances between the inner portion and the first segments.

The biaxial flexure bearing 540 discussed above uses torsion webs that are able to slightly twist in order to allow for a limited range of biaxial angular movement. Other types of biaxial flexure bearings may be used as well, e.g., biaxial flexure bearings with bending webs. An example of such a biaxial flexure bearing is depicted in FIGS. 6 through 10.

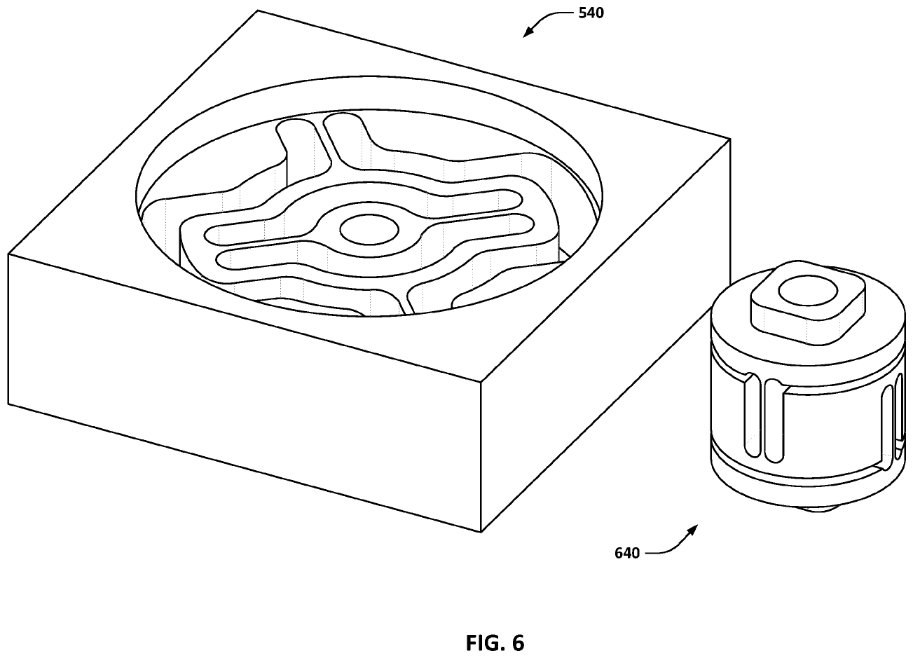

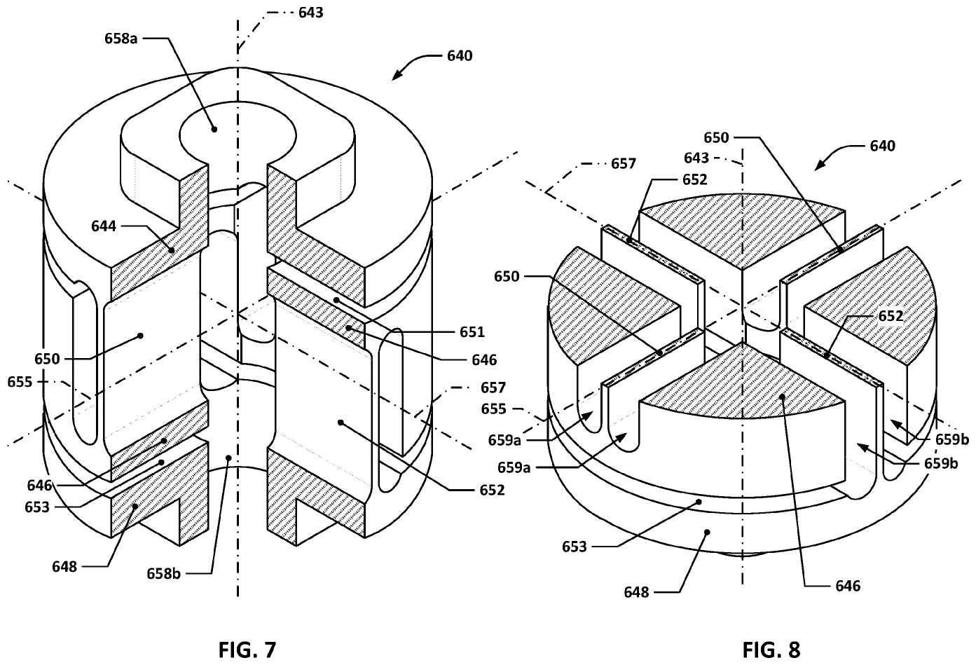

FIG. 6 is an isometric view of the biaxial flexure bearing 540 next to a biaxial flexure bearing 640. As can be seen, the biaxial flexure bearing 540 is designed to be machined directly into a larger structure, such as a plate that acts as the movable mount or the stationary mount in a hexapod system (in the depicted example, the biaxial flexure bearing 540 is shown as part of a small, square plate that may, it will be understood, simply be a portion of a much larger structure). The biaxial flexure bearing 640, in contrast, is designed to be coupled in between two components. For example, the biaxial flexure bearing 640 may have mount holes 658a and 658b (not shown, but visible in FIG. 7) that are each threaded (threads not shown) to allow the biaxial flexure bearing 640 to be threaded onto threaded studs or bolts or screws at both ends. In some implementations, the biaxial flexure bearing 640 is designed to be inserted in between the linear actuators of a hexapod mechanism and the stationary or movable mounts of the hexapod mechanism, therefore requiring more separation distance between the stationary and movable mounts of the hexapod mechanism than would be required in a hexapod mechanism using the biaxial flexure bearings 540. However, the overall diameter and size of the biaxial flexure bearing 640 may be much smaller, e.g., 50% smaller, than the torsion-based biaxial flexure bearing 540 (the biaxial flexure bearings 540 and 640 shown in FIG. 6 provide similar angular movement capabilities).

FIGS. 7 and 8 depict isometric cutaway views of the biaxial flexure bearing 640. In FIG. 7, one quadrant of the biaxial flexure bearing 640 has been cut away to reveal the interior of the biaxial flexure bearing 640. In FIG. 8, the upper half of the biaxial flexure bearing 640 has been cut away to reveal a transverse cross-section of the biaxial flexure bearing 640.

As can be seen in FIGS. 7 and 8, a center hole extends along a common axis 643 through the biaxial flexure bearing 640. The ends of the center hole may provide a first mount hole 658a and a second mount hole 658b. The first mount hole 658a and the second mount hole 658b may be threaded or otherwise include features allowing the biaxial flexure bearing 640 to be connected with a linear actuator or a stationary or movable mount. The center hole may extend, as shown in FIG. 7, through the entire length of the biaxial flexure bearing 640 in some cases, but in other cases, the center hole may not extend all the way through the biaxial flexure bearing 640.

The biaxial flexure bearing 640 may include a first portion 644, a second portion 646, and a third portion 648 that may all lie along the common axis 643 such that the second portion 646 is in between the first portion 644 and the third portion 648. A first gap 651 may exist between the first portion 644 and the second portion 646, while a second gap 653 may exist between the second portion 646 and the third portion 648.

A pair of first bending webs 650 may span between the first portion 644 and the second portion 646, and a pair of second bending webs 652 may span between the second portion 646 and the third portion 648. The first bending webs 650 and the second bending webs 652 may each be a relatively thin, beam-like structure (similar to the torsion webs discussed earlier) that are each very stiff in bending about one axis that is perpendicular to the common axis 643 and quite flexible in bending about another axis that is also perpendicular to the common axis 643 but is also perpendicular to the other axis as well. By having the first bending webs 650, which may generally define and be aligned with a first reference plane, and the second bending webs 652, which may generally define and be aligned with a second reference plane, arranged such that the first and second reference planes are perpendicular to one another, the first portion 644 and the third portion 648 are both able to angularly deflect relative to the second portion 646 about orthogonal bending axes that are perpendicular to the common axis 643. This allows the first portion 644 and the third portion 648 to engage in biaxial bending relative to one another, similar to the movement allowed by the biaxial flexure bearing 540. For example, the first portion 644 and the third portion 648 may angularly flex about a first axis 655 through bending of the first bending webs 650, while the first portion 644 and the third portion 648 may angularly flex about a second axis 657 through bending of the second bending webs 652.

The first bending webs 650 may be formed, for example, by machining (for example, via milling or wire electrical discharge machining) two first through-holes 659a that pass through the biaxial flexure bearing 640 along the first axis 655. The first through-holes 659a may be positioned close together and have generally flat sides where the two first through-holes 659a are closest to one another such that the little material that is positioned between the two first through-holes 659a forms the first bending webs 650. Similarly, the second bending webs 652 may be formed by machining two second through-holes 659b that pass through the biaxial flexure bearing 640 along the second axis 657. The second through-holes 659b may similarly be positioned close together and may have generally flat sides where the two second through-holes 659b are closest to one another such that the material that is positioned between the two through-holes 659b forms the second bending webs 652.

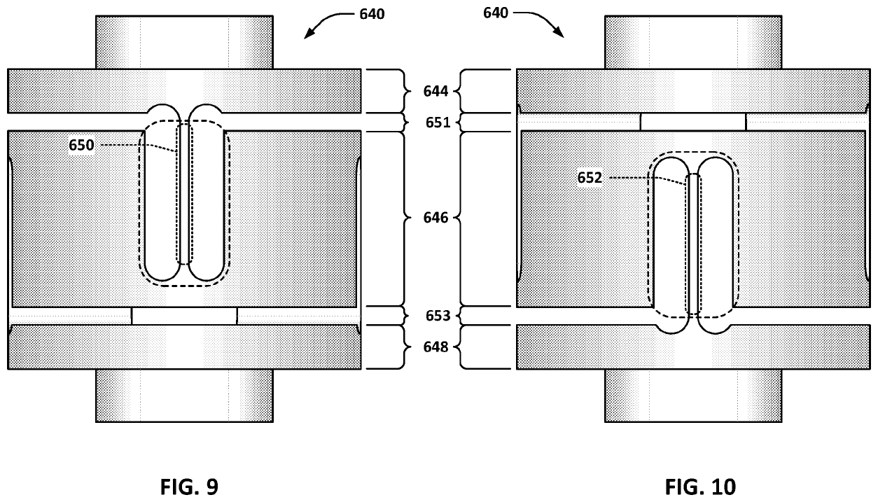

FIGS. 9 and 10 depict side views of the biaxial flexure bearing 640. As can be seen, the first bending webs 650 and the second bending webs 652 both extend into the second portion 646 by a significant amount, thereby resulting in a substantial amount of overlap between the first bending webs 650 and the second bending webs 652 along the common axis. This allows the axes about which the first bending webs 650 and the second bending webs 652 respectively bend to be close together. In some implementations, the first bending webs 650 and the second bending webs 652 may be designed to overlap each other completely along the common axis 643, in which case the respective bending axes for the first bending webs 650 and the second bending webs 652 may be in the same plane that is perpendicular to the common axis 643. In such an implementation, the first portion 644 and the third portion 648 may be able to flex angularly (about the first axis 655 and/or the second axis 657) about a single virtual point, e.g., similar to a kinematic connection made via a ball joint.

Either of the biaxial flexure bearings 640 and 540 may be used to provide flexible kinematic joints for use in hexapod mechanisms, e.g., between the linear actuators thereof and the movable and/or stationary mounts thereof. The biaxial flexure bearing 640 may provide a greater range of motion in a smaller packaging envelope since the compliant elements (the bending webs) flex in bending; in comparison, the biaxial flexure bearings 540's compliant elements flex in torsion, requiring that the lengths of the torsion webs be much longer than the lengths of the bending webs in order to provide the same amount of angular deflection. The biaxial flexure bearings 640, however, may also be somewhat less stiff than equivalent counterpart biaxial flexure bearings 540, however. Regardless, either type of biaxial flexure bearing may be used in the concepts discussed herein. In some instances, both biaxial flexure bearings 540 and 640 can be used in a single hexapod mechanism. Additionally, it will be understood that other types of biaxial flexure bearings may be used as well—the present disclosure is not to be limited to only the specific examples discussed herein.

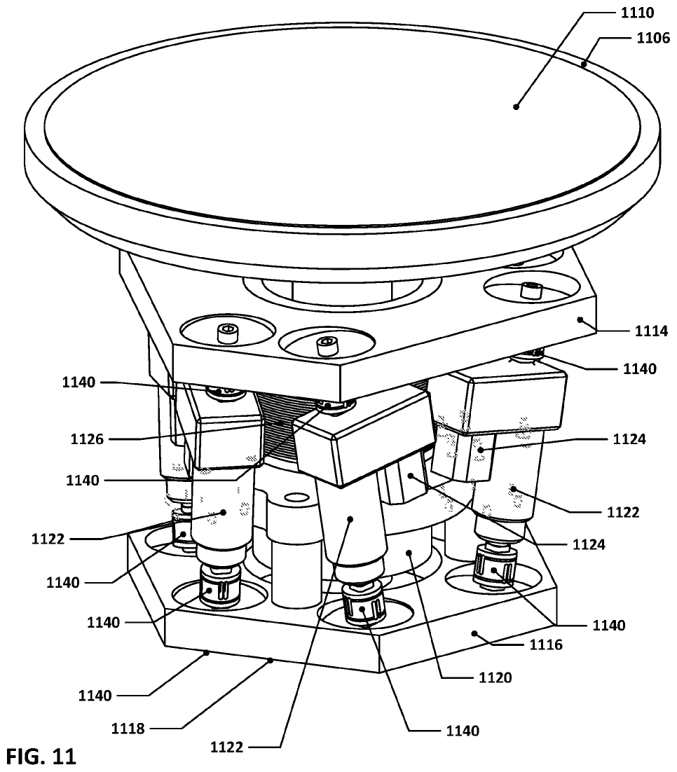

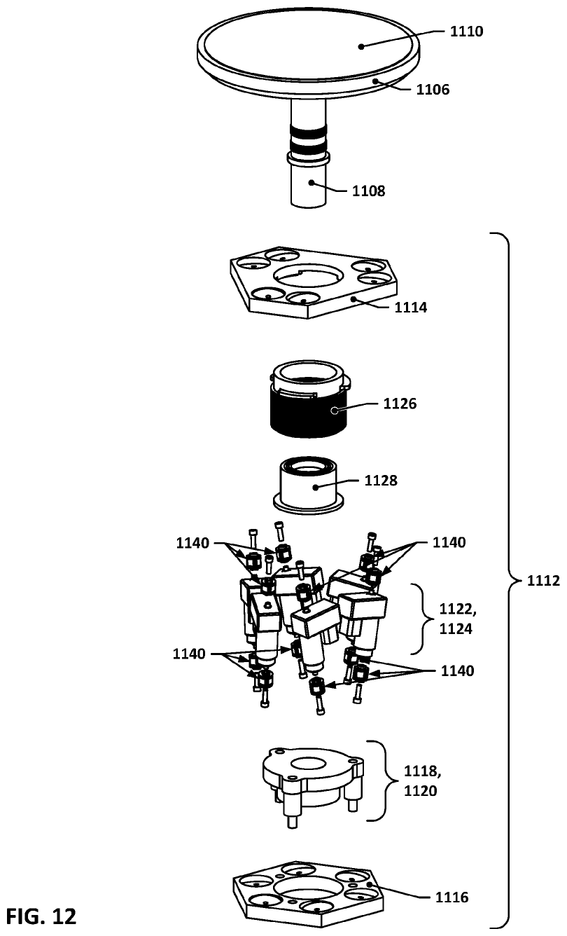

FIG. 11 depicts a dimetric view of the example hexapod-based pedestal system similar to that of FIG. 1 but using biaxial flexure bearings similar to those shown in FIGS. 7-8. FIG. 12 depicts a dimetric exploded view of the example hexapod-based pedestal system of FIG. 11. Most of the elements shown in FIGS. 11 and 12 are identical to those shown in FIGS. 2 and 4 and are indicated by callouts having the same last two digits as the counterpart element callouts in FIGS. 2 and 4. In the interest of brevity, these elements are not discussed again here; reference may be made to the earlier discussion of such elements provided with respect to the implementation of FIGS. 2 and 4.

As can be seen, the implementation of FIGS. 11 and 12 differs from that of FIGS. 2 and 4 in several respects. For example the linear actuators 1122 are somewhat shorter in length and are coupled at either end with a biaxial flexure bearing 1140. The biaxial flexure bearings 1140 are similar in design to the biaxial flexure bearing 640 discussed above.

The stationary mount 1114 and the movable mount 1116, as can be seen, have fixed mounting locations where the biaxial flexure bearings 140 are located in the embodiment of FIGS. 2 and 4. The biaxial flexure bearings 1140 are, as shown, connected with these mounting locations via a screw or other fastener.

It is to be understood that the biaxial flexure bearings described above are, in themselves, a discrete element of this disclosure and may be implemented (and claimed) in isolation from the hexapod systems discussed herein.

While hexapod-based pedestal systems that include biaxial flexure bearings such as the biaxial flexure bearings 140 (or other flexure bearings with different configurations but which still provide for biaxial rotation) may offer particular benefits in some usage contexts for hexapod-based pedestal systems, it will be understood that this disclosure is not limited to such implementations. Moreover, it is to be understood that the use of hexapod mechanisms that feature precision universal joints in place of the biaxial flexure bearings 140 for each linear actuator 122, or that use a universal joint and a spherical joint in place of the biaxial flexure bearings 140 for each linear actuator 122, is also considered to be within the scope of this disclosure.

Returning to FIGS. 1-4, it can be seen that the movable mount 116 is connected with the support column 108, and thus the pedestal 106, by way of an adapter plate 120 that is connected with the movable mount 116 by a plurality of standoffs 118. It will be understood, of course, that the adapter plate 120 and standoffs 118 may be omitted, with a direct connection between the support column 108 and the movable mount 116 (or that the adapter plate 120 and standoffs 118 may also be considered to be part of the movable mount 116). Regardless, the support column 108 and the pedestal 106 may be fixed with respect to, and supported by, the movable mount 116. In some implementations, however, the support column 108 may be mounted to the movable mount 116 by way of a rotational interface (not shown), e.g., a precision bearing system, so as to allow the pedestal 106 to be rotated about a rotational axis relative to the movable mount 116. A separate drive motor (not shown) may be provided to provide rotational input to the support column 108 to allow such rotation to be controlled. Such an implementation may allow for the pedestal to be rotated about its center axis without regard for whatever limitations the hexapod mechanism 112 may have with respect to such motion.

Another feature that is shown in FIGS. 1 through 4 is a bellows 126 and a ferrofluidic seal 128. In the depicted semiconductor processing tool 100, the semiconductor processing chamber is kept under a vacuum and is thus sealed off from the surrounding environment. The bellows 126 (shown in FIG. 1 as having rigid end portions joined by a flexible pleated structure) is a stainless steel bellows that is resistant to chemical attack from process gases used within the semiconductor processing chamber 102 and is provided to bridge the gap that exists between the semiconductor processing chamber 102 and the support column 108. The interface between the bellows 126 and the support column 108 may, in some implementations, be provided by a rotational seal, e.g., a ferrofluidic seal 128, that may allow the support column 108 to rotate relative to the bellows 126 and the semiconductor processing chamber 102. It will be understood that the rotational seal may alternatively be located at the other end of the bellows 126, e.g., such that it rotationally couples the upper end of the bellows 126 to the semiconductor processing chamber 102 (or to some other component that is fixed with respect to the semiconductor processing chamber 102, such as the stationary mount 114). In such an alternative implementation, the other end of the bellows 126 would be fixedly mounted with respect to the support column 108 so that the bellows 126 is caused to rotate with the rotation of the support column 108.

Bellows such as the bellows 126, i.e., made of stainless steel are typically engineered to support axial compression or extension of the bellows, but, due to the modulus of elasticity of steel and the geometry of the bellows, have poor translation accommodation capabilities in directions transverse to the extension axis thereof. However, the relatively low amounts of such transverse movement that a hexapod-based pedestal system may be expected to undergo are generally low enough that such bellows are nonetheless able to accommodate such displacements without compromising the seal.

If active rotation of the pedestal 106 about the yaw axis is desired, the use of the rotational seal, e.g., the ferrofluidic seal 128, allows the pedestal 106 to be rotated relative to the bellows 126 (or the bellows 126 to be rotated relative to the semiconductor processing chamber). As discussed above, a bellows such as the bellows 126 typically freely accommodates axial extension or retraction, and can accommodate a limited amount of transverse displacement between ends of the bellows as well as some angular rotation of the ends of the bellows about axes that lie in a plane that is perpendicular to the extension axis of the bellows. Such bellows, however, are typically very stiff in torsion about the extension axis. As a result, the bellows 126, without the use of the rotational seal, e.g., the ferrofluidic seal 128, will act to prevent any rotation of the pedestal 106 with respect to the semiconductor processing chamber 102. If such rotation is not desired for a particular semiconductor processing tool 100, then the rotational seal that is shown may be omitted even if the bellows 126 is present. However, if such rotational movement capability is desired, then the rotational seal that is shown, or some other similar rotational seal interface, may be used to provide a vacuum-tight rotational interface that allows one end or the other of the bellows 126 to rotate relative to either the support column 108 or the semiconductor processing chamber 102.

The ferrofluidic seal 128 that is pictured is only one example of a rotational seal that may be used to provide a vacuum-tight rotational seal interface that may be used to accommodate rotational movement between the support column 108 and the semiconductor processing chamber 102. In a ferrofluidic seal, a first part, e.g., a shaft, is rotatably supported relative to a second part, e.g., a casing or housing, by way of two or more rotational bearings 130. The casing or housing may contain a pair of rings 134 made of a material capable of being magnetized. Each ring 134 may encircle a different portion of the first part that has a series of multiple circumferential rib portions 136. One or more magnets 132 that are axially interposed between the rings 134 may cause a magnetic field to develop that passes through one of the rings 134, through the ribbed portion 136 encircled by that ring, through the first part (of the support column 108, for example), to the other ribbed portion 136, into the other ring 134, and back into the one or more magnets 132. A ferrofluidic material 138 that is introduced into the gaps between the rings 134 and the rib portions 136 that they encircle is, in effect, held in place by the magnetic field. The ferrofluidic material 138 spans across the radial gaps between the ribs and the encircling rings, thereby providing a series of annular, fluid-based seals that nonetheless allow for rotational movement between the first and second parts of the ferrofluidic seal.

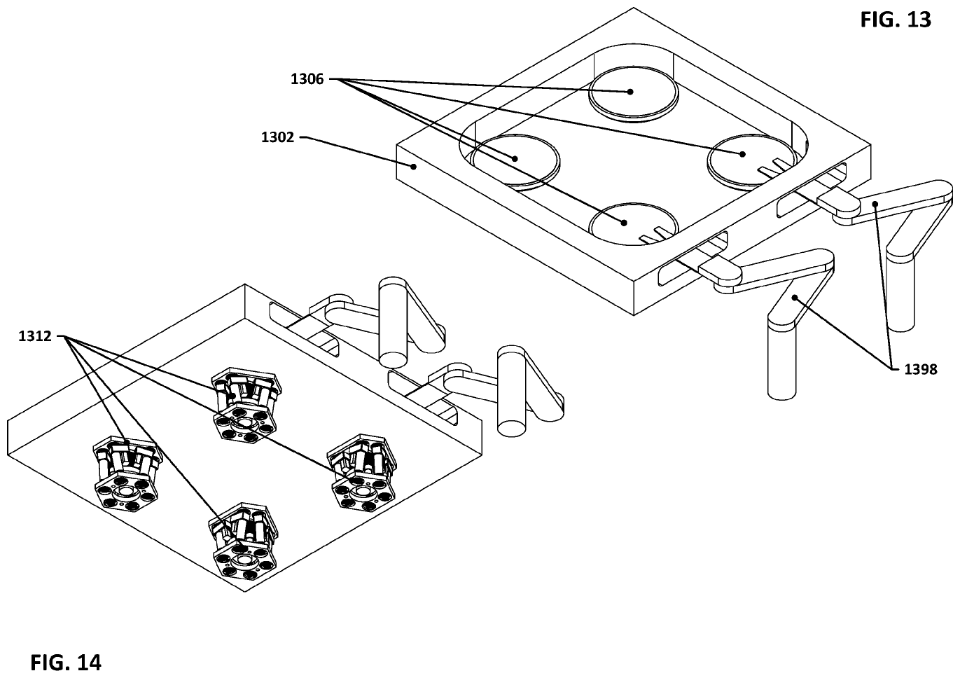

As mentioned earlier, hexapod-based pedestal systems may also be implemented in the context of multi-station chambers, e.g., quad-station modules or other multi-station chambers. FIGS. 13 and 14 depict views of an example quad-station module. In FIGS. 13 and 14, a processing chamber 1302 is depicted that is large enough to contain four pedestals 1306 that are arranged in a square array. A rotational indexer (not shown) may be included in the semiconductor processing chamber 1302 in some implementations to facilitate movement of wafers between the pedestals 1306. Two wafer handling robots 1398 are also shown; the wafer handling robots 1398 may be configured to reach into the semiconductor processing chamber 1302 in order to deliver wafers to the interior of the semiconductor processing chamber 1302 (or retrieve wafers therefrom). As can be seen in FIG. 14, each pedestal 1306 is supported by a corresponding hexapod mechanism 1312 and is independently controllable according to any of the techniques discussed herein.

General kinematics of hexapod mechanisms, e.g., how to extend or retract the linear actuators of a general hexapod mechanism so as to cause the movable mount thereof to move to a particular position and/or orientation relative to the stationary mount, are well-known and are thus not described in this disclosure in the interest of brevity (for example, the paper titled “Kinematic and dynamic analysis of Stewart platform-based machine tool structures,” by Khalifa Harib and Krishnaswamy Srinivasan, published September 2003 and hereby incorporated herein by reference in its entirety), provides a detailed discussion of the kinematics of hexapod mechanisms). However, various techniques for controlling and using a hexapod-based pedestal system in the context of a semiconductor processing chamber or tool, some of which were touched on previously, are discussed in more detail below.

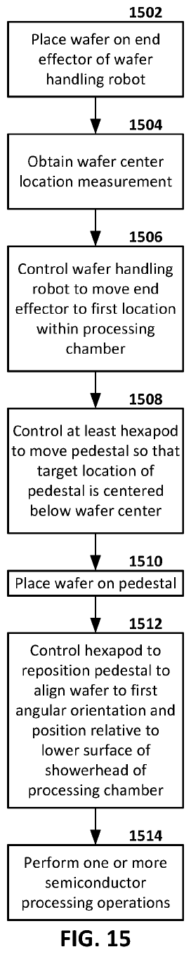

FIG. 15 depicts a flow chart for an example technique for using/controlling a hexapod-based pedestal system for wafer centering operations. The technique of FIG. 15 may be practiced when the control system of the hexapod-based pedestal system has previously been provided with various reference positions/orientations for the movable mount of the hexapod mechanism that is used. For example, the control system may be provided with information regarding a “loading” position and orientation of the movable mount and a “default processing” position and orientation of the movable mount, as well as a reference wafer center location that is associated with the loading position. The loading position and orientation corresponds with the location and orientation that the movable mount was in during a calibration operation that was performed with a calibration wafer that was theoretically centered on a desired target location of the pedestal. If the hexapod mechanism is positioned in the loading position and orientation and a wafer is positioned in the same position and orientation that the calibration wafer was in immediately before or after a wafer hand-off operation thereof between the end effector of a wafer handling robot and the pedestal, then the wafer should also be similarly centered on the target point if handed off to the pedestal with the hexapod-based pedestal system in the loading position. The reference wafer center location, for example, may correspond with the location of the center of the calibration wafer as measured by an AWC system in association with such a calibration operation.

Similarly, when the hexapod-based pedestal system is in the default processing position and orientation, this may position the pedestal such that the wafer support surface of the pedestal is parallel to, and at a preset distance from, the bottom surface of the showerhead of the semiconductor processing chamber and such that an axis that passes through the target location of the pedestal and that is also perpendicular to the wafer support surface passes through a target location on the showerhead, e.g., the center of the showerhead.

The loading and default processing positions and orientations may, as noted above, be obtained during calibration operations that may be performed during initial configuration or set-up of the hexapod-based pedestal system in the semiconductor processing tool. Some examples of such calibration techniques are discussed later herein with reference to later Figures.

It will be understood that reference herein to “target locations” with respect to pedestals and/or showerheads is intended to refer to locations with which the centers of wafers are to be aligned in some respect. For example, the target location of a pedestal would generally coincide with a location that was intended to be coincident with a point on the underside of a wafer that is at the nominal center point of the wafer when the wafer is supported by the wafer support surface thereof. The target location of a pedestal may also be referred to as the “center” of the pedestal or the wafer support surface thereof, although such a location may not necessarily be coincident with a geometric center axis of the pedestal. Rather, the “center” of the pedestal is viewed as that location on the pedestal that generally corresponds to the location on which wafers are to be centered when ideally placed in preparation for semiconductor processing operations.

Similarly, the target location of a showerhead would generally coincide with a location that is intended to intersect with an axis that is perpendicular to the wafer support surface of the pedestal and that passes through the target location of the pedestal when the pedestal is positioned such that the wafer support surface is parallel to the underside of the showerhead.

In block 1502, a wafer is placed on an end effector of a wafer handling robot (or on a wafer support at the end of a rotational indexer arm). In block 1504, a wafer center location measurement is obtained. For example, the wafer handling robot may be caused to move the end effector thereof, and thus the wafer supported thereby, through optical beams emitted by optical beam sensors of an AWC system so as to obtain measurements that allow the center of the wafer to be determined. For example, the AWC system may have two optical beam sensors that are fixedly mounted with respect to the semiconductor processing chamber and that are each configured to emit an optical beam in the vertical direction and to detect interruption (or non-interruption) of that optical beam. The optical sensors may be positioned such that the edge of the wafer intersects the optical beams emitted thereby as the wafer is passed into the semiconductor processing chamber—thereby producing four edge/beam intersection events (two that occur when the wafer intersects with, and blocks, each optical beam, and two that occur when the wafer exits, and stops blocking, each optical beam). By using the position of the wafer handling robot end effector (which may be determined based on the kinematic state of the wafer handling robot) that corresponds with each edge/beam intersection event and the diameter of the wafer, the AWC system is able to determine a center location of the wafer with respect to a coordinate system that is fixed with respect to the semiconductor processing chamber.

In block 1506, the wafer handling robot may be further controlled to move the end effector thereof, and the wafer placed thereupon, to a first location within the semiconductor processing chamber. The first location may, for example, be the same location that the wafer handling robot caused the end effector to move to during the calibration process prior to transferring the calibration wafer between the pedestal and the end effector (or vice versa). Thus, if the AWC-determined center of the wafer supported by the end effector is the same as the AWC-determined center of the calibration wafer from the calibration process (and if the wafer handling robot is caused to exactly replicate the movements of the wafer handling robot during the calibration process), the wafer would, with the end effector being in the first location, thus be in the same position as the calibration wafer was during the calibration process when the end effector was similarly in the first position.

In block 1508, the hexapod mechanism may be controlled so as to cause the movable mount thereof to move so as to align the target location of the pedestal such that it is aligned with the center of the wafer. For example, if the AWC-determined center point of the wafer is identical to that of the AWC-determined center point of the calibration wafer, then the hexapod mechanism may simply be controlled so as to cause the movable mount thereof to move into the loading position and orientation. In such a scenario, the positions and orientations of the wafer handling robot, the wafer, and the pedestal will be identical to the positions and orientations of those same components during the calibration operation prior to, or just after, transfer of the calibration wafer between the pedestal and end effector. As such, transfer of the wafer to the pedestal under such conditions should result in the wafer being centered on the target location of the pedestal with the same degree of precision with which the calibration wafer was centered on the target location of the pedestal during the calibration process.

In the event that the AWC-determined center of the wafer is not identical to the AWC-determined center of the calibration wafer, however, the amount and direction of offset between the AWC determined center of the calibration wafer and the AWC-determined center of the wafer may be determined. For example, it may be determined that the AWC-determined center of the wafer is 1 mm, −0.5 mm (in terms of XY coordinates relative to frame of reference that is fixed with respect to the semiconductor processing chamber) displaced from the AWC-determined center of the calibration wafer, then the hexapod mechanism may be caused to move the movable mount to a location and orientation that is displaced from the loading position and orientation by the same amounts. Thus, when the wafer is subsequently transferred from the end effector to the pedestal, e.g., by extending lift pins to lift the wafer off of the end effector, retracting the end effector from underneath the wafer, and then lowering the wafer onto the pedestal, the wafer center will be centered on the target location of the pedestal.

It will be understood that a similar end result may also be achieved in a variety of ways. For example, the wafer handling robot does not necessarily need to be moved to the same location as it was during the calibration process—as long as the wafer handling robot is controlled so as to position the wafer with its center point in a known location, the hexapod mechanism may be controlled so as to cause the pedestal to move such that the target location of the pedestal is aligned with that known location. Alternatively, the hexapod mechanism may be caused to remain stationary and the wafer handling robot may instead be caused to adjust its movements so as to correct out any misalignment that is detected for the wafer using the AWC system (as would typically be done in non-hexapod-based pedestal systems).

In block 1510, the wafer may be caused to be placed on the pedestal. For example, as discussed above, lift pins may be caused to extend upwards from the pedestal so as to contact the underside of the wafer and lift the wafer off of the end effector. The wafer handling robot may then be controlled so as to cause the end effector to be withdrawn from the space between the wafer and the pedestal. Once the end effector is clear of the wafer, the lift pins may be caused to retract and lower the wafer onto the pedestal's wafer support surface. The wafer, at this point, will be centered on the target location of the pedestal.

In block 1512, the hexapod mechanism may be controlled so as to cause the movable mount to move to the default processing position and orientation, or to a position and orientation that are offset therefrom by some predetermined and desired amount(s). Thus, for example, the hexapod mechanism may be controlled so as to cause the movable mount to move to the default processing position and orientation, thereby positioning the pedestal with the wafer support surface parallel to, and offset by a predetermined distance from, the underside of the showerhead and with an axis that passes through the target location of the pedestal and that is perpendicular to the wafer support surface thereof intersecting the target location of the showerhead. Alternatively, the hexapod mechanism may be controlled so as to simply move the pedestal to the desired location directly, without first moving the movable mount to the default processing position. The hexapod mechanism may then be controlled so as to cause the pedestal to translate along that axis so as to either increase or decrease the gap between the wafer support surface and the underside of the showerhead according to the needs of a particular process. Such adjustment may, in some cases, be performed dynamically during wafer processing operations as part of a process recipe.

In block 1514, one or more semiconductor processing operations may be performed on the wafer, e.g., by flowing one or more processing gases out of the showerhead, exposing the wafer to a plasma, heating the wafer, etc.

When processing operations are complete, the hexapod mechanism may be controlled so as to return the movable mount to the loading position and orientation, and a wafer handling robot may then be caused to remove the wafer from the pedestal and transport it to a new location for further processing or handling, e.g., to another pedestal or chamber, or to a load lock for removal from the semiconductor processing tool.

As discussed above, the hexapod-based pedestal systems discussed herein may be used to dynamically adjust the size of the gap between the pedestal wafer support surface and the underside of the showerhead. Hexapod-based pedestal systems may also, however, be used to perform a variety of other wafer position and orientation adjustments-either dynamically during wafer processing operations or prior to wafer processing operations.

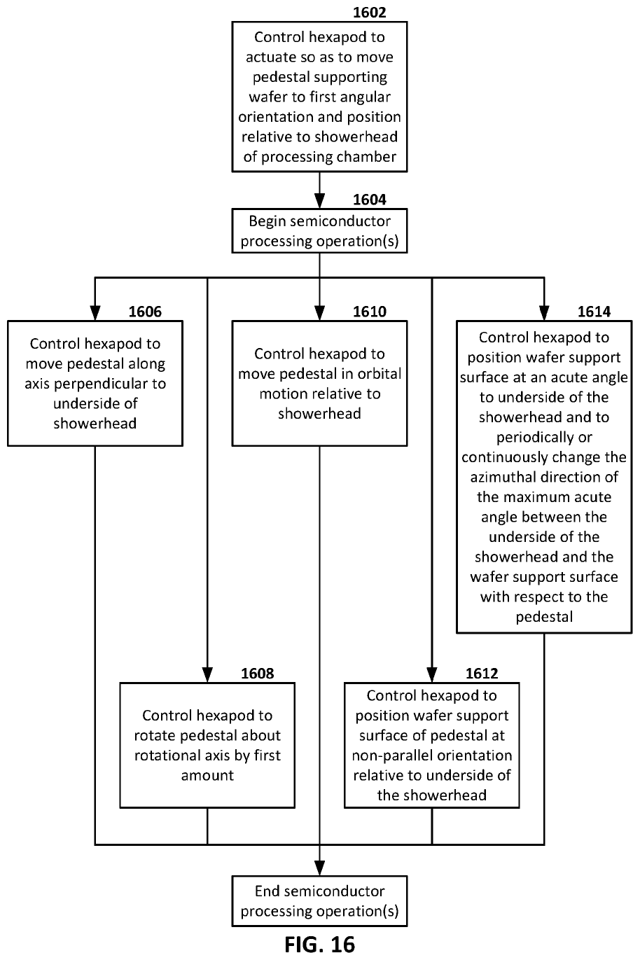

FIG. 16 depicts an example of a technique for utilizing a hexapod-based pedestal system to perform various types of pedestal movements that may be used to enhance various wafer processing operations. In block 1602, a hexapod mechanism of a hexapod-based pedestal system may be actuated so as to move the pedestal thereof that is supporting a wafer to a first position and angular orientation relative to a showerhead of the semiconductor processing chamber that is interfaced with the hexapod-based pedestal system. The first position and angular orientation may, for example, coincide with the default processing position and orientation of the movable mount, as discussed earlier.

In block 1604, semiconductor processing operations may be caused to begin being performed on the wafer. For example, the wafer may be subjected to heating and/or cooling via temperature control systems housed in the pedestal, process gases flowed from the showerhead, and/or plasma that may be formed in the gap between the pedestal and the showerhead.

Blocks 1606-1612 represent various different types of movement that the hexapod may be controlled so as to provide. Depending on the particular requirements of a semiconductor processing operation, one or more (or, alternatively, none) of the indicated movements may be caused to occur through control of the hexapod mechanism. It will be further understood that, in some instances, two or more of the indicated movements may be caused to be performed simultaneously (or at least partially simultaneously), or that two or more different indicated movements may be caused to occur sequentially, or in an permutation (including repetitions of one or more such indicated movements).

In block 1606, the hexapod mechanism may be controlled so as to cause the pedestal to translate along an axis that is perpendicular to the underside of the showerhead, e.g., as discussed earlier above with respect to FIG. 15. The discussion herein has referred to the underside of the showerhead in a manner that suggests that the underside of the showerhead is planar, e.g., “perpendicular to the underside” or “the gap between the wafer support surface and the underside of the showerhead.” It is to be understood, however, that the underside of the showerhead may, in some instances, be non-planar, e.g., contoured. In such cases, the underside of the showerhead defines a reference plane that, it will be understood, is viewed in this application as representing the underside of the showerhead. Thus, “perpendicular to the underside” would be understood, for such a showerhead, to mean “perpendicular to the reference plane that represents the underside of the showerhead.” Such a reference plane is, for example, the plane that is oriented and positioned such that it has the lowest average spatially distributed distance between itself and all points on the underside surface of the showerhead. Thus, for example, if the underside of the showerhead were to be contoured to have a radial sinusoidal cross-sectional profile, the reference plane would be parallel to the X-axis of the sinusoidal profile and located approximately midway between the uppermost and lowermost portions of the sinusoidal profile.

Such translational movement of the pedestal may cause the gap that exists between the pedestal wafer support surface and the showerhead to be dynamically adjusted. This may, for example, allow for tuning of the radial flow conductance of gas that is flowed into the gap between the pedestal wafer support surface and the showerhead to be increased or decreased, the volume of gas (and thus the gas flow rate) that must be flowed into the space between the pedestal and the wafer support surface to be increased or decreased, the properties of an electromagnetic field that exists between the wafer support surface and the showerhead to be adjusted or tuned, and so forth.

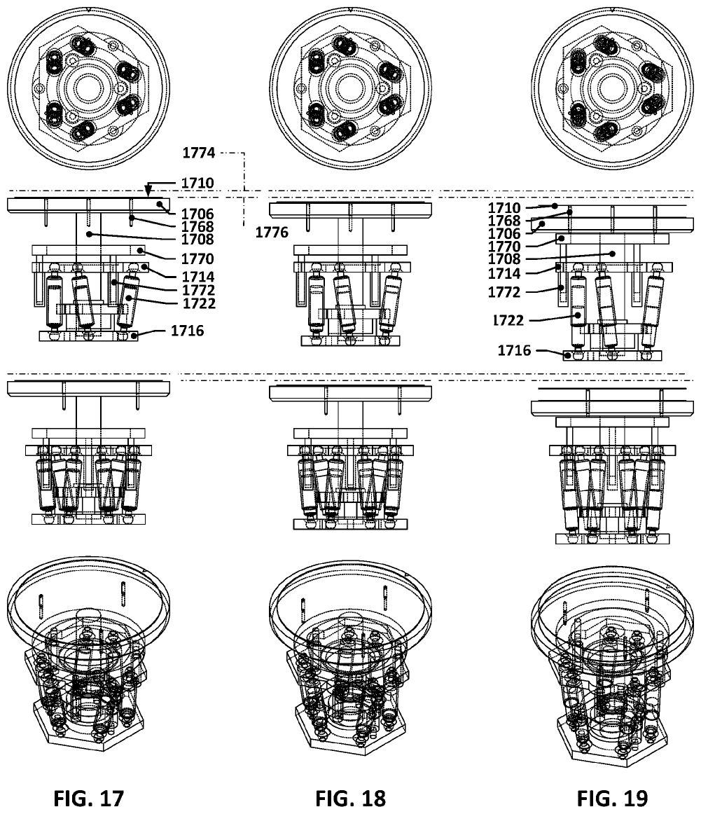

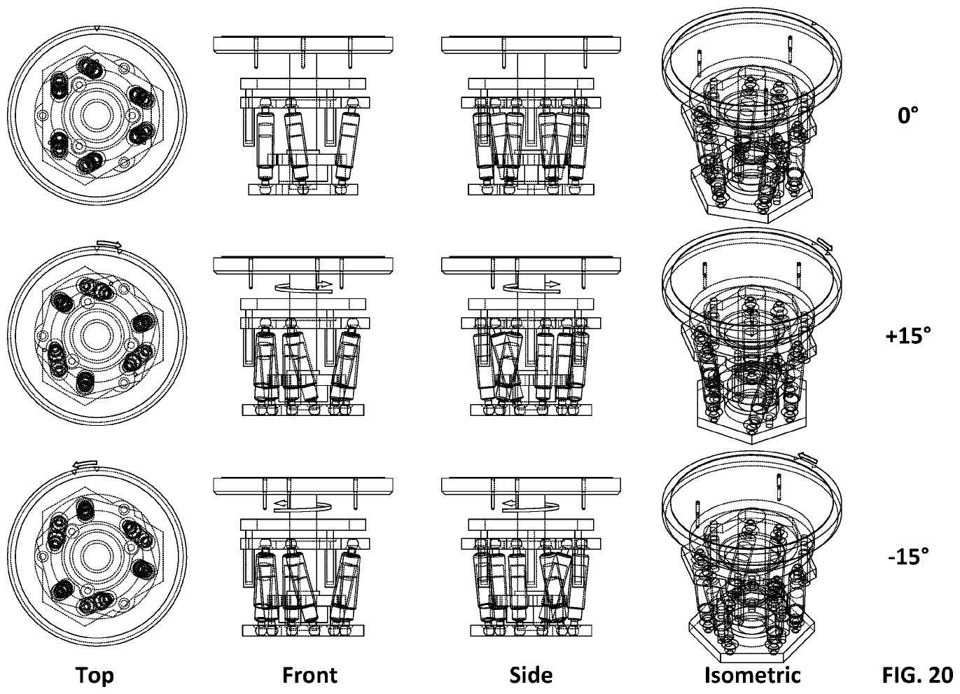

Examples of such translation movement are depicted in FIGS. 17 through 19, which show a hexapod-based pedestal system (with chamber, bellows, and rotational seal(s) omitted from view) in various states of operation (and from various perspectives, e.g., top, side, front, and isometric). The hexapod-based pedestal system of FIGS. 17 through 19 (which is also shown in FIGS. 20 through 23) features a movable mount 1716 that is connected to a stationary mount 1714 by six linear actuators 1722. The linear actuators 1722 are, in this example, shown as being connected at either end with the movable mount 1716 or the stationary mount 1714 via spherical joints for the purposes of illustration, although it will be understood that alternate versions may utilize the flexure bearings discussed earlier herein, or universal joints.

As shown in FIGS. 17 and 18, the linear actuators 1722 may be controlled so as to raise or lower the pedestal 1706. For example, in FIG. 17, the linear actuators 1722 have been caused to retract, thereby causing the movable mount 1716 and the pedestal 1706 supported thereby to elevate to a highest elevated position 1776. The highest elevated position 1776 may, for example, be vertically offset from a plane 1774 that is coincident with the underside of a showerhead (not shown). The linear actuators 1722 may similarly be partially extended in order to cause the movable mount 1716 to descend relative to the stationary mount 1714, thereby lowering the pedestal 1706, as shown in FIG. 18.

The hexapod-based pedestal system of FIGS. 17 through 19 also includes a lift-pin mechanism with a plurality of lift pins 1768 that are slidably engaged with a pedestal 1706 that is supported by the movable mount 1716 by a support column 1708. The lift pins 1768 may protrude out from the underside of the pedestal 1706 and may be fully retracted below the wafer support surface of the pedestal when in a retracted state, but may also be caused to be extended from the wafer support surface (thereby lifting any wafer that may be supported by the wafer support surface) by applying a lifting force to the tips of the lift pins 1768 that protrude out from the bottom of the pedestal 1706. For example, a lift pin actuation mechanism that includes a lift ring 1770 may be provided. The lift ring 1770 may encircle the support column 1708 and be supported by lift actuators 1772 that may be controlled so as to raise or lower the lift ring 1770. For example, the lift ring 1770 may be raised so as to contact the tips of the lift pins 1768 that protrude out from the underside of the pedestal 1706, thereby causing the lift pins to extend out from the wafer support surface of the pedestal in order to either lift a wafer up off of the pedestal, e.g., as shown in FIG. 19, or to lift a wafer supported on an end effector of a wafer handling robot that is positioned above the pedestal 1706 off of the end effector. In FIG. 19, the lift ring 1770 has been lifted and the pedestal 1706 lowered further in order to provide a desired degree of pedestal 1706/wafer 1710 gap due to the lift pin 1768 actuation. Alternatively, the lift pin actuation mechanism may include individually controllable actuators that may be used to separately drive each lift pin rather than an actuator or actuators that drive the lift pins in unison via the lift ring 1770.

Referring back to FIG. 16, in block 1608, the hexapod mechanism may be controlled so as to cause the pedestal to be rotated about a rotational axis, e.g., a rotational axis that passes through the target location of the showerhead and that is perpendicular to the underside of the showerhead. Such rotation may, for example, be performed once or may be cyclical, e.g., rotation by +X° followed by rotation by −X°. Depending on the particular configuration of hexapod mechanism used, e.g., a hexapod mechanism with universal/spherical joints vs. a hexapod mechanism with biaxial flexure joints, the amount of such rotation that may be supported may be relatively large, e.g., up to ±30°, or quite small, e.g., ±3° (or even non-existent). Such rotational movement may be used to reduce or average out azimuthal non-uniformities that may occur during semiconductor wafer processing operations.

FIG. 20 depicts the hexapod-based pedestal system of FIG. 17 undergoing rotational movement such as is discussed with respect to block 1608 in FIG. 16. The topmost row of views shows the hexapod-based pedestal system in a default or non-rotated state (or mid-range rotated state, i.e., the hexapod-based pedestal system can be caused to rotate by equal amounts in either direction). The middle row of views shows the hexapod-based pedestal system actuated so as to cause the pedestal to rotate by 15 degrees in a clockwise direction (when viewed from above) about a rotational axis that passes through the center of the pedestal 1706 (refer to FIG. 17 for callouts). The bottom row of views shows the hexapod-based pedestal system actuated so as to cause the pedestal to rotate by 15 degrees in a counterclockwise direction (when viewed from above) about the rotational axis. To aid in perceiving the rotational movement, the pedestal 1706 is equipped with a triangular fiducial feature that indicates the rotational orientation of the pedestal 1706 (the same triangular feature is also shown in both the displaced and un-displaced states in the ±15° figures).

Referring back to FIG. 16, in block 1610, the hexapod-based pedestal system may be controlled so as to cause the pedestal to orbit around a location that is offset from the target location of the showerhead. Thus, for example, the hexapod mechanism may be controlled so as to cause the target location of the pedestal to move off-center from being centered on the target location of the showerhead. Subsequent to, or during, such movement, the hexapod mechanism may be controlled so as to cause the target location of the pedestal to translate so as to follow a spiral, circular, elliptical, or other path that orbits around an axis that is perpendicular to the underside of the showerhead and that passes through the target location of the showerhead. Such orbital motion of the pedestal about such an axis may be used to reduce or average out non-uniformities, particularly those that are focused or concentrated in small areas (e.g., areas at least smaller than the maximum dimensions of the orbital path used).

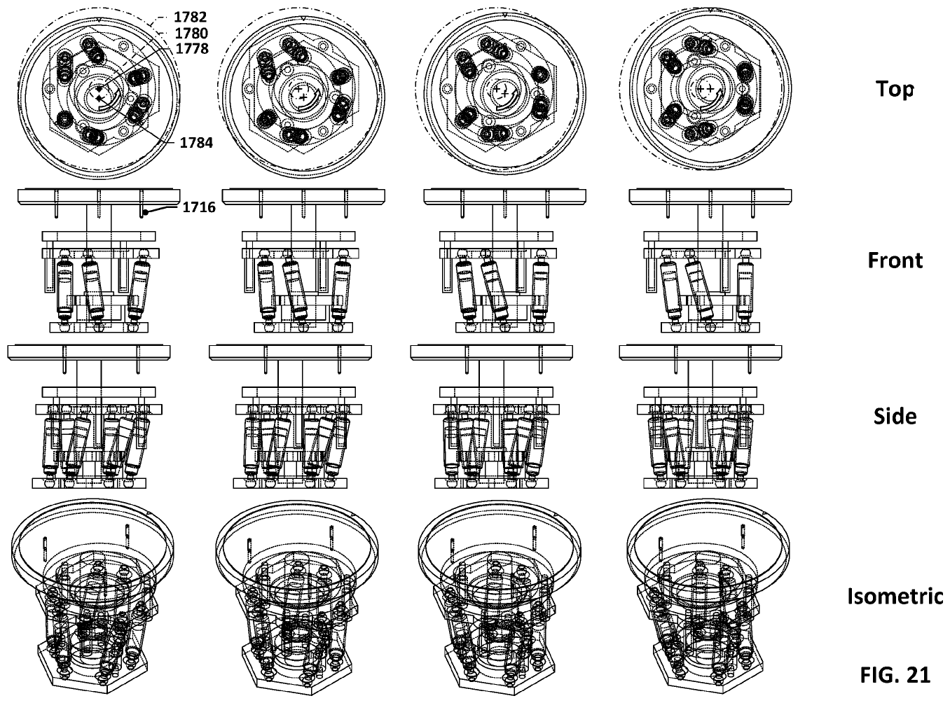

FIG. 21 depicts the hexapod-based pedestal system of FIG. 17 undergoing orbital movement such as is discussed with respect to block 1610 in FIG. 16. In FIG. 21, the hexapod-based pedestal system is shown at four different stages of an orbital movement. In the left-most set of views, the hexapod-based pedestal system has been actuated so as to laterally offset the pedestal center 1784 from an orbital center axis 1778, e.g., a center axis of the pedestal 1706 when the pedestal 1706 is in a default or centered position (see reference position 1782 of the pedestal) with respect to, for example, a showerhead. The pedestal center 1784 may thus lie along an orbital path 1780 that is centered on the orbital center axis 1778 and be caused, as shown in each set of views progressing towards the right in FIG. 21, to follow the orbital path 1780. In FIG. 21, only a quarter of an orbit is shown, but it will be understood that the movement depicted may be continued for a full orbit (or multiple orbits). Additionally, as can be seen, the orbital movement of the pedestal may be caused to occur without any rotational orientation change with respect to the pedestal (the triangular fiducial marks indicating rotational orientation do not, as evident from the top views, indicate any rotation)—of course, combining the movements of block 1610 with those of block 1608 would result in both orbital and rotational movement of the pedestal 1706.

Referring back to FIG. 16, in block 1612, the hexapod mechanism may be controlled so as to cause the wafer support surface of the pedestal to deliberately adopt a non-parallel orientation with respect to the underside of the showerhead. In some such implementations, such movement may be controlled so as to cause the target location of the pedestal to remain centered on an axis that passes through the target location of the showerhead and that is perpendicular to the underside of the showerhead, although in other implementations, such movement may be controlled such that the target location of the pedestal is offset radially from such an axis.

For example, the hexapod mechanism may be controlled so as to cause the pedestal to move to an orientation such that the wafer support surface thereof is at a small, non-zero acute angle with respect to the underside of the showerhead, e.g., ˜0.1° to 2°. Such non-parallelism between the wafer support surface and the underside of the showerhead may result in a change in radial flow conductance of process gas flowed into the gap between the wafer support surface and the showerhead, e.g., there may be higher flow conductance in radial directions that extend towards edge portions of the pedestal where the wafer support surface/showerhead underside angle causes a larger gap therebetween to exist as compared with radial directions in the opposite directions (which extend towards edge portions of the pedestal where the above-referenced angle causes a smaller gap to exist). Depending on the particular process, such higher flow conductance may result in either an increase or decrease in the processing rate of the process in question, e.g., etch or deposition, in the higher-flow-conductance areas. Such tuning of the flow conductance may allow for certain types of non-uniformities to be mitigated. For example, in a multi-station processing chamber, there may be four pedestals at four stations that are arranged to form the corners of a square. A rotational indexer that rotates about an axis that is centered at the center of the square may be used to transfer wafers between the various stations. However, the presence of the rotational indexer may result in significant asymmetries in the geometry of the processing chamber surrounding each station. For example, if the processing chamber has cylindrical bores around each pedestal/station, this may provide a relatively uniform radial gap between the pedestals and the portions of the processing chamber that are closest to the outer edge of the pedestal. However, if the walls of the bores are machined away in some locations to allow for the indexer arms to rotate into the areas above the pedestals, those locations become discontinuities in the cylindrical surfaces of the bores that may result in the wafers being processed developing a gradient non-uniformity that extends more or less along diameters of the wafers. By tilting the pedestal slightly to deliberately introduce a similar non-uniformity gradient in the opposite direction, the magnitude of the non-uniformity may be reduced or eliminated.

Such tilting may also, for example, be used to counter potential circumferential gas flow non-uniformity that may exist due to asymmetries in the exhaust system of a semiconductor processing chamber. For example, if a semiconductor processing chamber has an exhaust system that is fluidically connected with the interior volume of the semiconductor processing chamber at a location that is horizontally offset from a vertical axis that passes through the target location of the pedestal, this may cause a circumferential pressure gradient to exist around the perimeter of the pedestal, thereby causing potential circumferential flow non-uniformity about the perimeter of a wafer even in situations where the semiconductor processing chamber is otherwise axially symmetric in the regions surrounding the pedestal and the wafer support surface and the underside of the showerhead are parallel. By deliberately tilting the wafer support surface with respect to the underside of the showerhead, the circumferential gas flow non-uniformity that may develop due to such exhaust system asymmetries may potentially be mitigated or countered through introduction of a countervailing circumferential gas flow non-uniformity caused by tilting the wafer support surface relative to the underside of the showerhead. For example, if the exhaust system fluidically connects with the semiconductor processing chamber at a location that is at 0° clocking orientation about a vertical axis that passes through the target location of the pedestal, the hexapod mechanism may be controlled so as to tilt the pedestal and the wafer support surface thereof such that a location along the edge of a wafer supported thereby that is at ˜180° clocking orientation about the vertical axis (e.g., on an opposite side of the location where the exhaust system fluidically connects with the semiconductor processing chamber) has the largest gap between the wafer edge and the underside of the showerhead, while a location along the edge of the wafer that is at ˜0° clocking orientation about the vertical axis has the closest gap between the wafer edge and the underside of the showerhead.

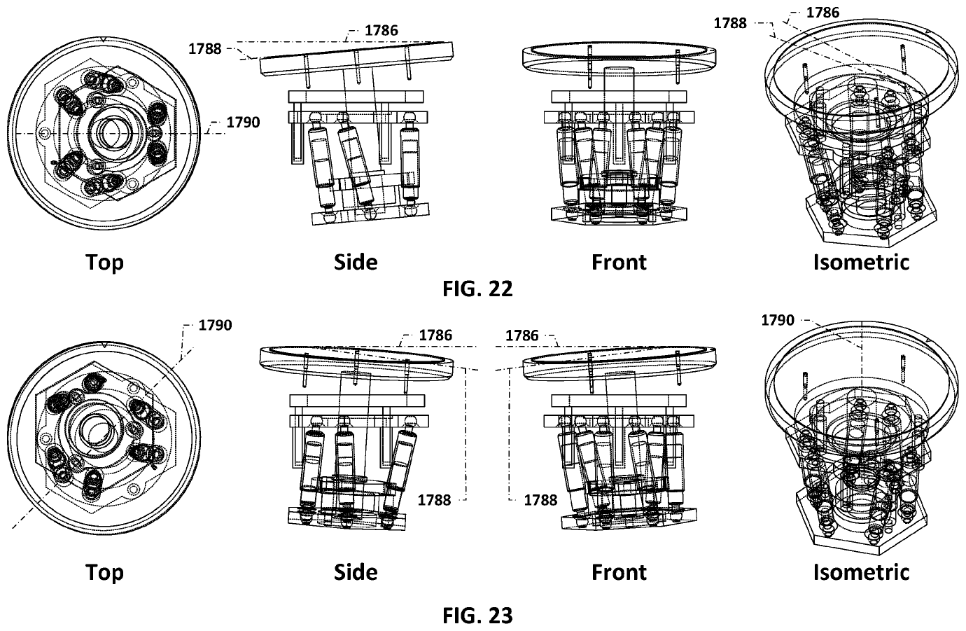

FIG. 22 depicts the hexapod-based pedestal system of FIG. 17 with the pedestal 1706 inclined so as to be non-parallel to a horizontal plane 1786 (taken as a representative parallel proxy to the underside of a showerhead for the purposes of this example). Line 1788 represents a plane that is coplanar with the wafer support surface of the pedestal 1706, and line 1790 represents a plane that is perpendicular to both of the planes 1786 and 1788. The maximum acute angle that exists between the planes 1786 and 1788 is defined by the angle between the lines formed by the intersections of those planes with the plane 1790. It will be appreciated that the amount of angular displacement (5°) that is shown in FIG. 22 is significantly exaggerated from what would likely actually be used in a hexapod-based pedestal system, e.g., ±0.2°; this is for illustrative purposes only.

Referring back to FIG. 16, in block 1614, the hexapod mechanism may be caused to move the pedestal in a manner similar to that discussed above with respect to operation 1612, i.e., to develop a non-parallel orientation between the wafer support surface of the pedestal and the underside of the showerhead. However, the hexapod mechanism is further controlled so as to cause the maximum acute angle that develops between the wafer support surface and the underside of the showerhead to periodically or continuously change its azimuthal direction with respect to the wafer support surface. The maximum acute angle, it will be understood, refers to the maximum acute angle that exists between the wafer support surface and the underside of the showerhead in a plane that is perpendicular to the underside of the showerhead. Similarly, the azimuthal direction of the maximum acute angle refers to a direction vector that is parallel to the underside of the showerhead and coincident with the plane in which the maximum acute angle exists.

Thus, for example, the hexapod mechanism may be controlled so as to cause the diametrically opposed locations along the perimeter of a wafer supported by the pedestal that are closest to, and furthest from, the underside of the showerhead to periodically or continuously move along the outer perimeter of the wafer. Such movement may appear somewhat similar to that which results from combining/simultaneously performing the operations of blocks 1608 and 1612, e.g., tilting the pedestal and wafer support surface with respect to the underside of the showerhead and then rotating the pedestal and tilted wafer support surface about a vertical axis, except that in the combination of the operations of blocks 1608 and 1612, the diametrically opposed points along the perimeter of the wafer supported by the wafer support surface that are closest and furthest from the underside of the showerhead do not change (thus, the same locations along the wafer perimeter remain the furthest/closest points to the underside of the showerhead, even during rotation of the pedestal via the operation of block 1612). In contrast, the operation of block 1614 causes such locations to periodically or continually advance around the perimeter of the wafer.

FIG. 23 depicts the hexapod-based pedestal system of FIG. 17 tilted as in FIG. 22 but with the azimuthal direction of the depicted maximum acute angle that is developed shifted by 45° counter-clockwise from the orientation that it is in in FIG. 22, e.g., similar to movement described above with respect to block 1614. Thus, the plane 1790 is shifted by 45° from its orientation in FIG. 22. As can be seen, the rotational orientation of the pedestal, aside from the rotations needed to achieve the depicted degree of tilt, does not change.

The movements described with respect to block 1614 may be used to induce a biased flow conductance between the wafer support surface (or wafer supported thereby) and the underside of the showerhead that is then caused to periodically or continuously rotate relative to the wafer support surface (and the wafer supported thereby). In effect, this may cause a circumferentially non-uniform gas flow rate to exist around the perimeter of the wafer, but may also cause the locations where the maximum and minimum gas flow rates occur to traverse around the perimeter of the wafer so as to evenly distribute or more evenly distribute the process gases being flowed.

As noted above, in some implementations, only one or a proper subset of the various operations of blocks 1606 through 1614 may be performed during a particular semiconductor processing operation or set of such semiconductor processing operations. Furthermore, whatever operations of blocks 1606 through 1612 are performed during a given set of one or more semiconductor processing operations may be performed separately in some instances or in combinations of two or more of such operations in other instances. For example, the orbital movement of block 1610 may be combined with the rotational movement of block 1608 to provide for even more averaging of any non-uniformities that may be present.

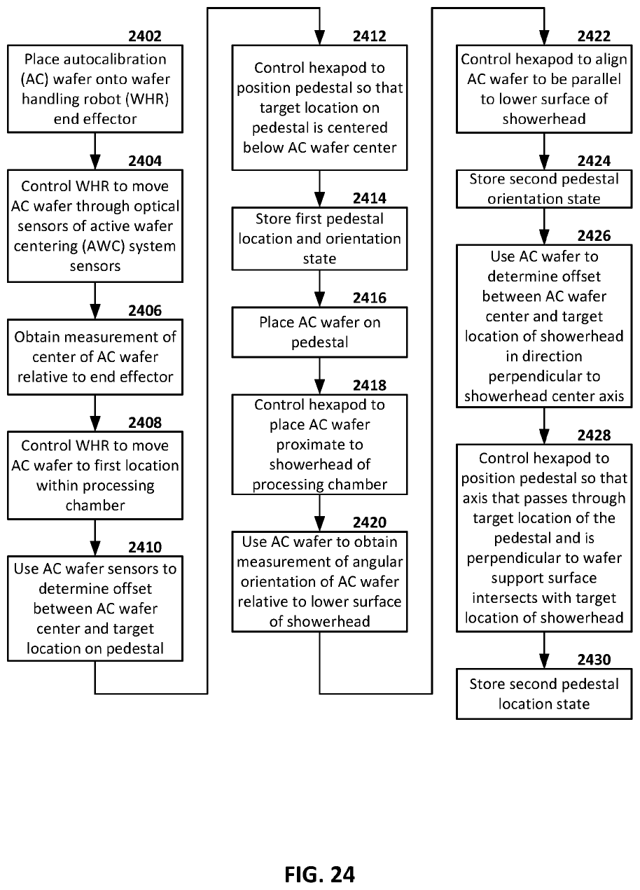

In some embodiments, hexapod-based pedestal systems may be calibrated during a calibration process in order to establish various parameters that may then be referenced during later use, e.g., when placing semiconductor wafers onto such pedestals or when positioning such pedestals in preparation for wafer processing operations. There may be a variety of techniques that may be used to obtain such information. In some embodiments, the various operations discussed above may be performed using such information without regard to how, exactly, such information was obtained. In the interest of providing a more detailed overview of how hexapod-based pedestal systems may be used, however, one such technique for obtaining such calibration information is discussed in more detail below with regard to FIG. 24.

The technique diagrammed in FIG. 24 is intended to be performed using an integrated, multi-sensor autocalibration wafer that is nominally the same size and shape as a normal semiconductor wafer but which includes a number of sensor systems that may be used during a calibration process to assist with obtaining the above-mentioned calibration information. The autocalibration wafer may, for example, serve as the calibration wafer discussed earlier herein. An example of an autocalibration wafer with similar capabilities, at least in some respects, is provided in PCT application publication WO2021022291, which was published on Feb. 4, 2021, and which is hereby incorporated by reference herein in its entirety and for all purposes. Such an autocalibration wafer may include, for example, multiple capacitance-based distance measurement sensors located along the upper surface that may be used to obtain capacitance-based measurements indicative of the distance between each distance measurement sensor and the underside of the showerhead (when sufficiently close to the showerhead), as well as imaging sensors that are configured to look both upward, towards the showerhead, and downward, towards the pedestal when such autocalibration wafers are positioned in between the pedestal and the showerhead.

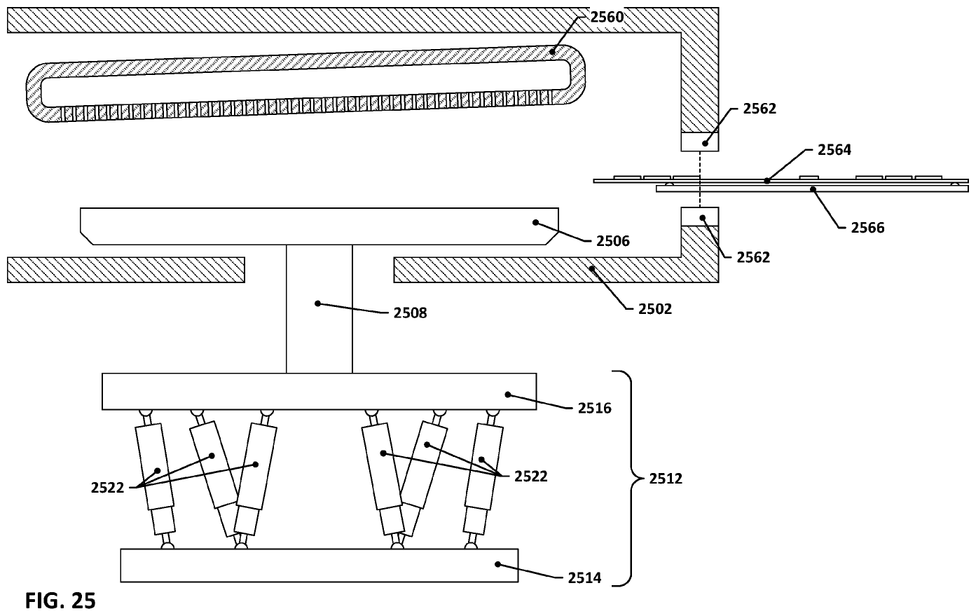

FIGS. 25 through 36 depict schematics of an example semiconductor processing tool and may be referenced in the discussion below. The example semiconductor processing tool features a semiconductor processing chamber 2502 that includes a showerhead 2560 and which is connected with a hexapod-based pedestal system including a pedestal mechanism 2512. For the purposes of illustration, the showerhead 2560 is shown with a significant amount of tilt/misalignment from horizontal. In actual practice, the showerhead 2560 may be configured so as to have a nominally horizontal bottom surface. However, due to assembly and machining tolerances, the showerhead 2560 may nonetheless have some small amount of tilt, e.g., ˜0.2° or less. The showerhead is shown floating in space but may, in practice, be supported by one or more other structures, or may be provided as part of the semiconductor processing chamber lid.

Also visible in FIG. 25 is a pedestal 2506 that is supported by a movable mount 2516 of the pedestal mechanism 2512 which is, in turn, coupled with a stationary mount 2514 thereof by six linear actuators 2522. The pedestal mechanism 2512 in this example is arranged differently than that discussed earlier with respect to other implementations in that the stationary mount 2514 and the movable mount 2516 have their relative positions reversed, but the fundamental operating principles are identical. If desired, the depicted hexapod mechanism may be replaced with one that is more similar to the version depicted in earlier examples (and vice-versa). The stationary mount 2514 is fixedly mounted with respect to the semiconductor processing chamber 2502.

FIG. 25 also depicts an autocalibration wafer 2564 that is supported by an end effector 2566 of a wafer handling robot that may be used to introduce wafers into, and remove wafers from, the semiconductor processing chamber 2502. A pair of AWC optical sensors 2562 may be mounted so as to be fixed with respect to the semiconductor processing chamber 102; each optical sensor 2562 may emit an optical beam, as discussed above and as indicated by the dotted line spanning from the upper portion to the lower portion of the optical sensor 2562 that is depicted; the other optical sensor 2562 may be positioned on an opposite side of the opening in the semiconductor processing chamber 2502 through which the end effector 2566 transports wafers such that the edge of the wafer(s) break the optical beams of both optical sensors 1662 as they transit through the opening.

In block 2402, the autocalibration wafer may be placed on the end effector of a wafer handling robot, much in the same manner than a wafer-to-be-processed would be placed on the end effector thereof. In some instances, the autocalibration wafer may be placed on the end effector with the assistance of a fixture that precisely locates the autocalibration wafer in a particular location and orientation with respect to the end effector.

In block 2404, the wafer handling robot may be controlled so as to cause the end effector to move the autocalibration wafer through optical sensors of an AWC system of a semiconductor processing chamber, e.g., as shown in FIG. 25. In block 2406, which may be performed during block 2404, the AWC system may determine a center location of the autocalibration wafer relative, for example, to a coordinate system that is fixed (or at least determinable) relative to the semiconductor processing chamber based on the data from the optical sensors. This center location may, for example, be stored for later reference, e.g., for use in determining the amount of offset between the center location of the autocalibration wafer as determined by the AWC and the center location of a wafer-to-be-processed by the AWC.

In block 2408, the wafer handling robot may be controlled so as to cause the end effector to move to a first position within the semiconductor processing chamber. The first position may, for example, be a position that is nominally centered over the target location of a pedestal of the hexapod-based pedestal system when the hexapod-based pedestal system is in a particular configuration, e.g., a home configuration (for example, with the actuators of the hexapod mechanism all at the same degree of extension).

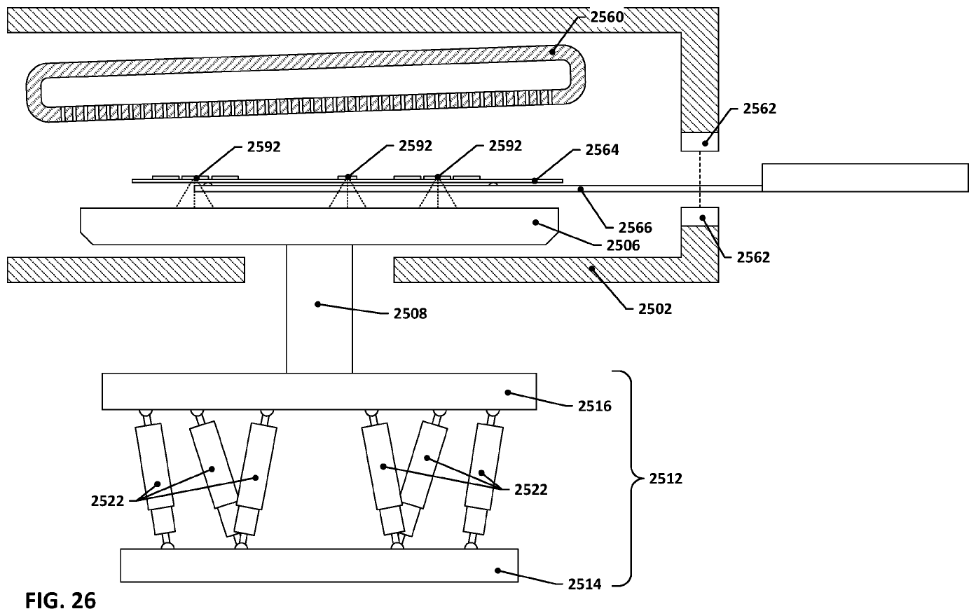

In block 2410, sensors of the autocalibration wafer may be used to determine a location of the target location of the pedestal relative to the center of the autocalibration wafer, e.g., as shown in FIG. 26. For example, downward-facing imaging sensors 2592 on the autocalibration wafer may be used to obtain image data of fiducials, e.g., visually detectable patterns, registration marks, etc., on the pedestal. The fiducials may have a known relationship with the target location of the pedestal, e.g., the fiducials may include multiple lines that, when extended towards the center of the pedestal, converge on a point that coincides with the target location of the pedestal. Alternatively, there may be a fiducial, e.g., two intersecting lines, that exists at the target location itself. In another example, an alignment fixture or jig that includes such fiducials may be temporarily placed on the pedestal and precisely positioned with respect to the pedestal using one or more physical alignment features; after such calibration operations are complete, such a fixture may be removed from the pedestal. The image data that is obtained may allow for the determination of the horizontal location of the target of interest of the pedestal with respect to the center location of the autocalibration wafer.

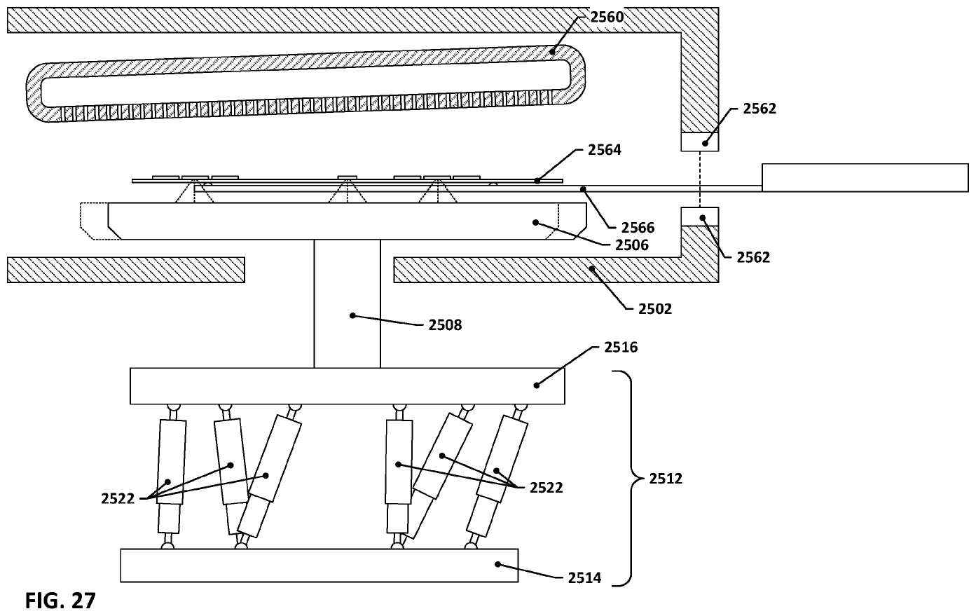

In block 2412, the hexapod mechanism of the hexapod-based pedestal system may be controlled so as to cause the pedestal to move by an amount that counteracts the horizontal offset that exists between the target location of the pedestal and the center of the autocalibration wafer as indicated by the image data. Thus, at the conclusion of block 2412, the target location of the pedestal will generally be positioned directly beneath, and centered on, the center of the autocalibration wafer, as shown in FIG. 27. In FIG. 27, the “default” position of the pedestal 2506 is shown as a dotted outline, with the pedestal 2506 displaced therefrom, as discussed above.

In block 2414, information describing the location and orientation of the hexapod mechanism's movable mount at the conclusion of block 2412 may be stored in memory as first position and orientation information for future retrieval. Such information may take any of a variety of forms but is sufficient to allow the position and orientation of the hexapod mechanism at the conclusion of block 2412 to be replicated in the future, as needed. Such information may, for example, include actuation state information for each of the actuators of the hexapod mechanism that indicates the position of each of the actuators. The information stored in block 2414 may, for example, be information that determines the loading position and orientation for the hexapod-based pedestal system, similar to that discussed earlier.

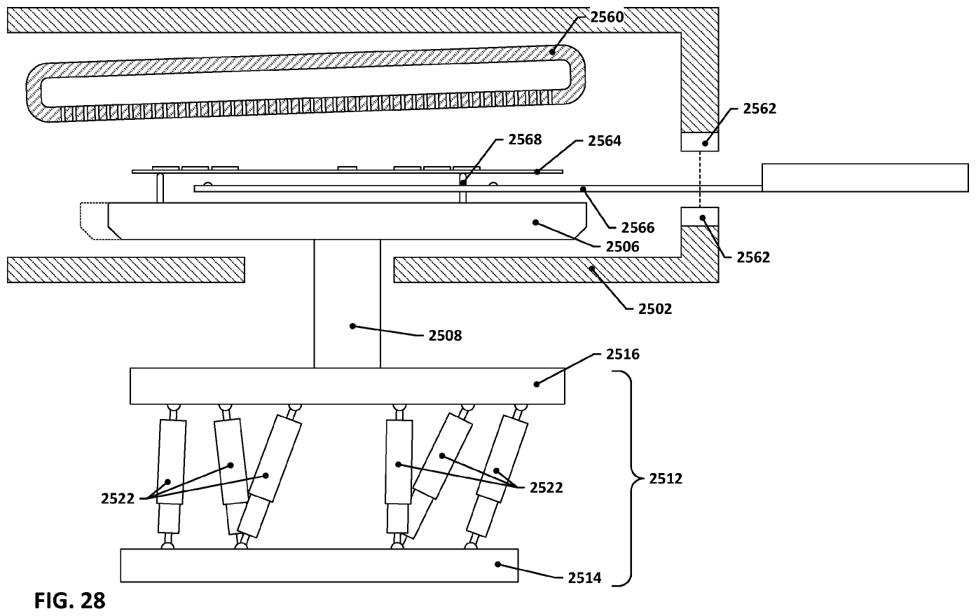

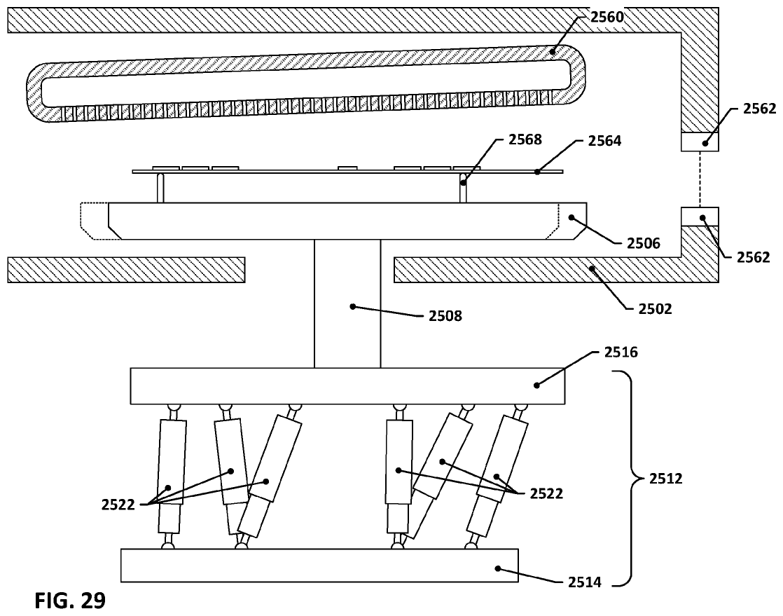

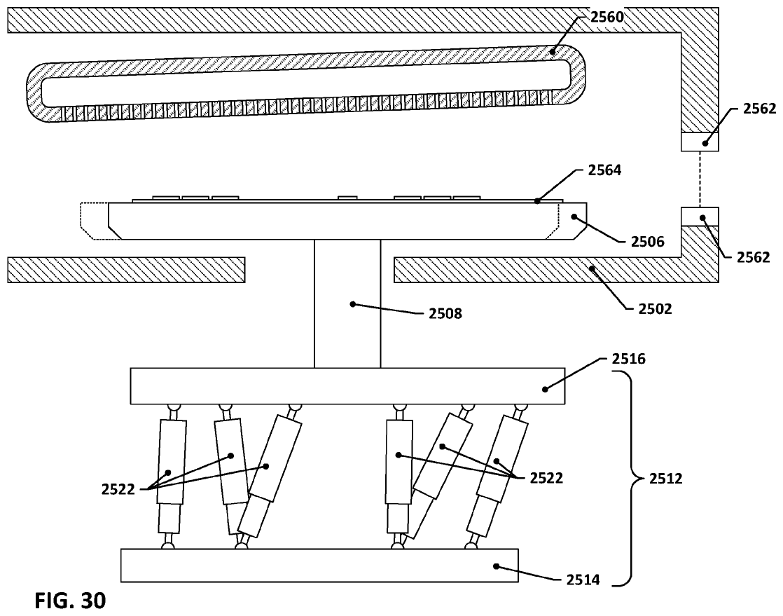

In block 2416, the autocalibration wafer may be placed onto the pedestal. For example, the pedestal may include a lift-pin mechanism that may be controlled so as to extend a plurality of lift-pins from the wafer support surface so as to lift the autocalibration wafer off of the end effector, e.g., as shown in FIG. 28. The end effector may then be withdrawn from underneath the autocalibration wafer (as shown in FIG. 29) and the lift-pins caused to retract back into the pedestal, thereby lowering the autocalibration wafer onto the wafer support surface (as shown in FIG. 30. At the conclusion of this operation, the autocalibration wafer will be supported by the pedestal and the center of the autocalibration wafer centered on the target location.

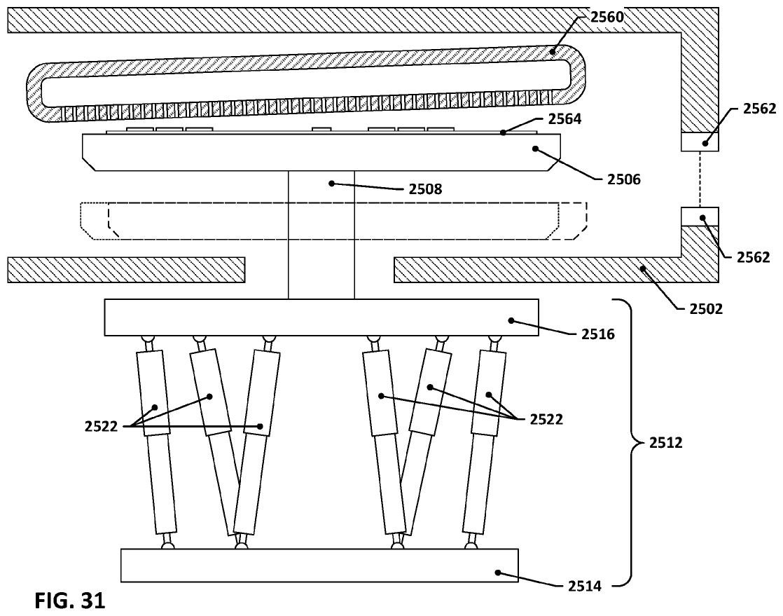

In block 2418, the hexapod mechanism may be controlled so as to cause the pedestal to be repositioned at a location that is proximate to the underside of the showerhead, as shown in FIG. 31. The location to which the pedestal is moved may be selected so as to be close enough to the showerhead that the capacitance-based sensors of the autocalibration wafer are able to obtain capacitance measurements regarding the gap between the autocalibration wafer and the underside of the showerhead. The location of the pedestal that results from the information stored as a result of block 2414 is indicated by a dashed outline of the pedestal in FIG. 31 and later Figures.

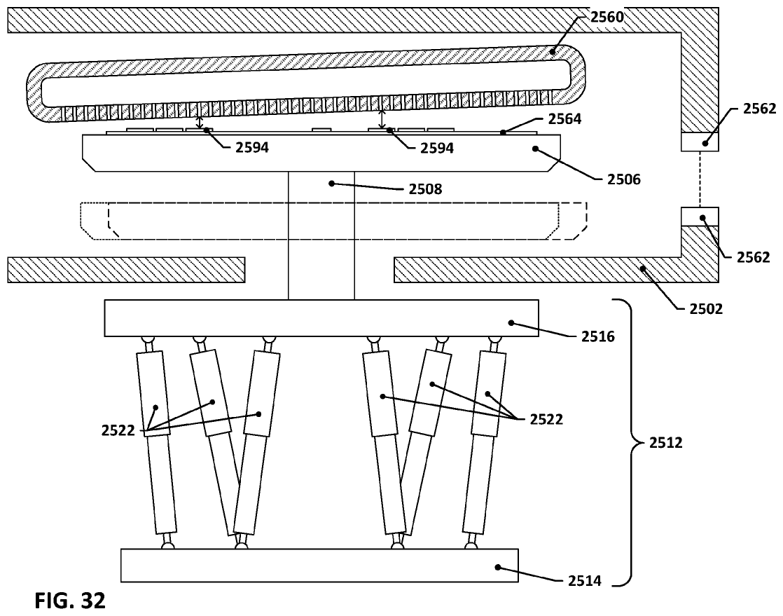

In block 2420, the capacitance-based distance sensors of the autocalibration wafer may be used to obtain information indicative of the angular orientation of the wafer support surface of the pedestal relative to the underside of the showerhead. For example, if there are three capacitance-based sensors, e.g., such as capacitance-based distance sensors 2594 in FIG. 32, located along the outer perimeter of the autocalibration wafer, the capacitance measured by each such sensor may be dependent on the size of the gap between that sensor and the underside of the showerhead. Thus, for example, if each such sensor is identically configured, the capacitances measured by such sensors would be the same if the gaps between the sensors and the showerhead underside are the same (and the wafer support surface thus parallel to the underside of the showerhead). Even if the sensors are not identical in size and performance, such sensors may be calibrated using an external fixture to determine a relationship between the capacitance measured by each sensor and the gap that exists between that sensor and the surface that forms the other portion of the capacitive circuit. Such calibration information may then be applied to the capacitance measurements obtained with respect to the showerhead underside in order to determine the actual relative distances between the sensors and the showerhead underside.

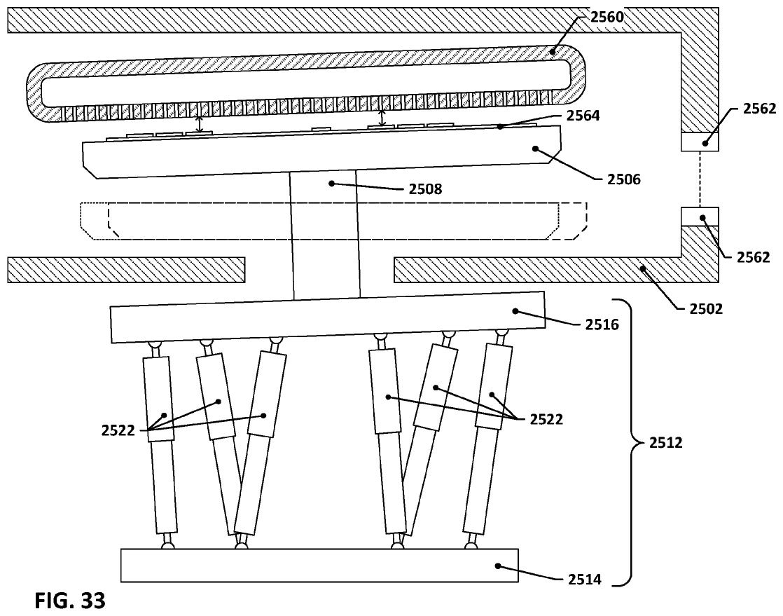

In block 2422, the hexapod mechanism may be controlled so as to adjust the orientation of the pedestal wafer support surface relative to the underside of the showerhead. For example, the hexapod mechanism may be controlled so as to tilt the pedestal such that the wafer support surface, and the autocalibration wafer supported thereby, tilt so as to cause the distances measured by the capacitance-based sensors to equalize, e.g., as shown in FIG. 33.

In block 2424, information indicative of the orientation state of the movable mount of the hexapod mechanism may be stored in memory for later reference as a second orientation state. The second orientation state may, for example, be an orientation state that serves as the default processing orientation discussed earlier herein.

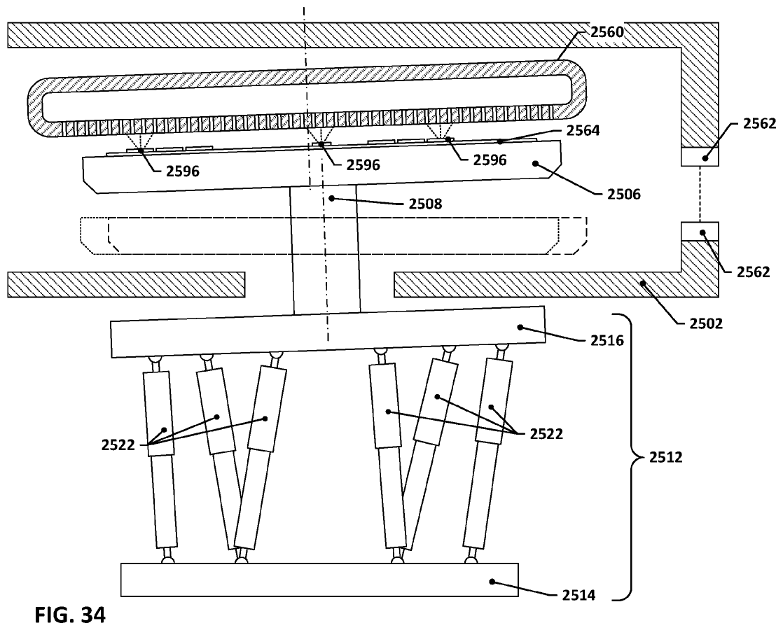

In block 2426, the upward-facing imaging sensors of the autocalibration wafer may be used to determine a location of the target location of the showerhead relative to the center of the autocalibration wafer, as shown in FIG. 34. For example, the upward-facing imaging sensors on the autocalibration wafer may be used to obtain image data of fiducials on the underside of the showerhead. The fiducials may have a known relationship with the target location of the showerhead, e.g., as with the pedestal fiducials, the fiducials may include multiple lines that, when extended towards the center of the showerhead, converge on a point that coincides with the target location of the showerhead. Alternatively, there may be a fiducial, e.g., two intersecting lines, that exists at the target location itself. In another example, an alignment fixture or jig that includes such fiducials may be temporarily placed on the showerhead and precisely positioned with respect to the showerhead using one or more physical alignment features; after such calibration operations are complete, such a fixture may be removed from the showerhead. The image data that is obtained may allow for the determination of the location of the target of interest of the showerhead with respect to the center location of the autocalibration wafer.

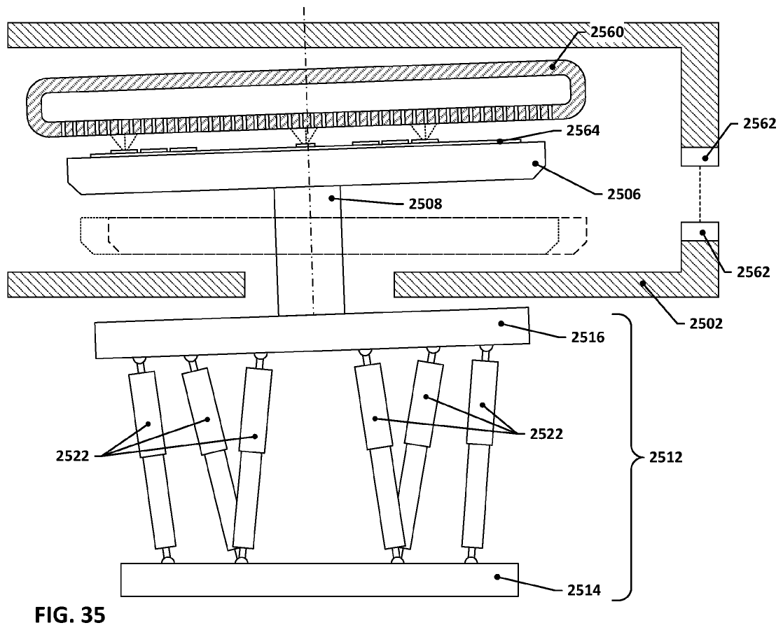

In block 2428, the hexapod mechanism may be controlled so as to move the pedestal, based on the information collected in block 2426, such that an axis that passes through the target location of the pedestal and that is normal to the wafer support surface passes through the target location of the showerhead. In FIG. 34, the target location of the showerhead is indicated by the dash-dot-dash center line that passes through the showerhead 2560. The target location of the showerhead, in this example, coincides with the location where that center axis intersects the underside of the showerhead. Similarly, the target location of the pedestal in this example coincides with the point of intersection between a center axis of the pedestal (shown as a dash-dot-dash centerline that passes through the support column 2508 and the pedestal 2506) with the wafer support surface of the pedestal 2506. In FIG. 35, the pedestal 2506 has been shifted such that the two axes align, e.g., such that the axis that passes through the target location of the pedestal and that is normal to the wafer support surface passes through the target location of the showerhead.

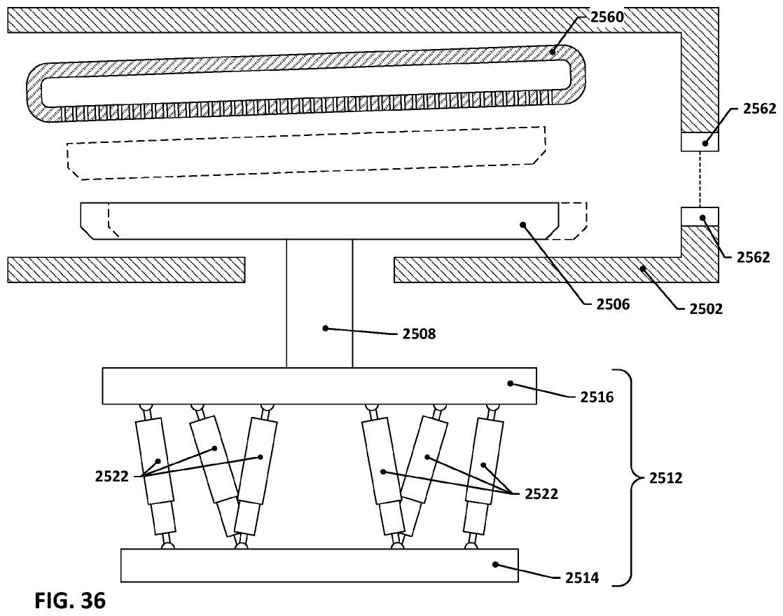

In block 2430, information indicating the position of the movable mount after the completion of block 2428 may be stored in memory as second position state information, e.g., information that may correspond with the default processing position discussed earlier herein. The pedestal may then, after removal of the autocalibration wafer, be returned to, for example, a default position as shown in FIG. 36. The upper dashed outline of the pedestal 2506 in FIG. 36 represents the location of the pedestal 2506 as defined by the second position and orientation state information, whereas the lower dashed outline of the pedestal 2506 in FIG. 36 represents the location of the pedestal 2506 as defined by the first position and orientation state information.

Thus, at the conclusion of the operations discussed above with respect to blocks 2402 through 2430, state information for the hexapod-based pedestal system indicating positional states of the movable mount of the hexapod mechanism for a wafer loading operation involving a “centered” wafer and for a default processing state in which the wafer support surface is parallel to, and a predefined distance from, the underside of the showerhead and the target locations of the showerhead and pedestal both lie along a common axis that is perpendicular to the wafer support surface. Additionally, wafer center location information for the autocalibration wafer as determined by the AWC system may be stored to allow offsets between the centers of future wafers determined by the AWC and the wafer center location for the autocalibration wafer to be determined to guide alignment of the pedestal with future wafer placement operations.

The control of a hexapod-based pedestal system, as well as potentially other equipment discussed above (such as wafer handling robots, indexers, active wafer centering systems, etc.) may be facilitated through the use of a controller that may be included as part of a semiconductor processing tool, including, for example, the above-described example semiconductor processing tools and/or chambers. The systems discussed above may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), valve operation, light source control for radiative heating, pressure settings, vacuum settings, power settings, radio frequency (RF) generator settings, RF matching circuit settings, frequency settings, flow rate settings, fluid delivery settings, positional and operational settings, wafer transfers into and out of a tool or chamber and other transfer tools and/or load locks connected to or interfaced with a specific system. More specifically, such a controller may be configured to control, among other systems, the linear actuators of a hexapod-based pedestal system. In some such implementations, the controller may also be configured to receive data from an autocalibration wafer or other calibration system that allows the controller to obtain information from sensor systems of the autocalibration wafer or other calibration system to facilitate calibration of the hexapod-based pedestal system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon oxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The use, if any, of ordinal indicators, e.g., (a), (b), (c) . . . or (1), (2), (3) . . . or the like, in this disclosure and claims is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated) unless indicated otherwise. For example, if step (ii) involves the handling of an element that is created in step (i), then step (ii) may be viewed as happening at some point after step (i). Similarly, if step (i) involves the handling of an element that is created in step (ii), the reverse is to be understood. It is also to be understood that use of the ordinal indicator “first” herein, e.g., “a first item,” should not be read as suggesting, implicitly or inherently, that there is necessarily a “second” instance, e.g., “a second item.”

It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise).

For the purposes of this disclosure, the term “fluidically connected” is used with respect to volumes, plenums, holes, etc., that may be connected with one another, either directly or via one or more intervening components or volumes, in order to form a fluidic connection, similar to how the term “electrically connected” is used with respect to components that are connected together to form an electric connection. The term “fluidically interposed,” if used, may be used to refer to a component, volume, plenum, or hole that is fluidically connected with at least two other components, volumes, plenums, or holes such that fluid flowing from one of those other components, volumes, plenums, or holes to the other or another of those components, volumes, plenums, or holes would first flow through the “fluidically interposed” component before reaching that other or another of those components, volumes, plenums, or holes. For example, if a pump is fluidically interposed between a reservoir and an outlet, fluid that flowed from the reservoir to the outlet would first flow through the pump before reaching the outlet. The term “fluidically adjacent,” if used, refers to placement of a fluidic element relative to another fluidic element such that there are no potential structures fluidically interposed between the two elements that might potentially interrupt fluid flow between the two fluidic elements. For example, in a flow path having a first valve, a second valve, and a third valve placed sequentially therealong, the first valve would be fluidically adjacent to the second valve, the second valve fluidically adjacent to both the first and third valves, and the third valve fluidically adjacent to the second valve.

The term “between,” as used herein and when used with a range of values, is to be understood, unless otherwise indicated, as being inclusive of the start and end values of that range. For example, between 1 and 5 is to be understood to be inclusive of the numbers 1, 2, 3, 4, and 5, not just the numbers 2, 3, and 4.

The term “operatively connected” is to be understood to refer to a state in which two components and/or systems are connected, either directly or indirectly, such that, for example, at least one component or system can control the other. For example, a controller may be described as being operatively connected with a resistive heating unit, which is inclusive of the controller being connected with a sub-controller of the resistive heating unit that is electrically connected with a relay that is configured to controllably connect or disconnect the resistive heating unit with a power source that is capable of providing an amount of power that is able to power the resistive heating unit so as to generate a desired degree of heating. The controller itself likely cannot supply such power directly to the resistive heating unit due to the currents involved, but it will be understood that the controller is nonetheless operatively connected with the resistive heating unit.

It is understood that the examples and embodiments described herein are for illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein but may be modified within the scope of the disclosure.

It is to be understood that the above disclosure, while focusing on a particular example implementation or implementations, is not limited to only the discussed example, but may also apply to similar variants and mechanisms as well, and such similar variants and mechanisms are also considered to be within the scope of this disclosure. In particular, this disclosure is directed to at least the following numbered implementations, but may also include additional implementations that are evident from the above discussion but not listed here.

Implementation 1: An apparatus including:
a pedestal configured to support a semiconductor wafer during wafer processing operations;
a hexapod mechanism that includes:
a movable mount that supports the pedestal;
a stationary mount; and
six independently controllable linear actuators, each linear actuator having a first end pivotably connected with the stationary mount and a second end pivotably connected with the movable mount, in which the linear actuators support the movable mount relative to the stationary mount.

Implementation 2: The apparatus of implementation 1, in which the linear actuators are arranged in a trilaterally symmetric manner.

Implementation 3: The apparatus of either implementation 1 or implementation 2, in which:
the six linear actuators are grouped into three sets of two linear actuators, and
the linear actuators in each pair of linear actuators are arranged so as to have first ends that connect with the stationary mount at locations that are closer together than locations where the second sends thereof connect with the movable mount.

Implementation 4: The apparatus of any of implementations 1 through 3, in which:
each first end of each linear actuator is pivotably connected with the stationary mount by a corresponding spherical joint, universal joint, or biaxial flexure bearing, and
each second end of each linear actuator is pivotably connected with the movable mount by a corresponding spherical joint, universal joint, or biaxial flexure bearing.

Implementation 5: The apparatus of any of implementations 1 through 3, in which
each first end of each linear actuator is pivotably connected with the stationary mount by a corresponding first biaxial flexure bearing.

Implementation 6: The apparatus of implementation 5, in which each first biaxial flexure bearing includes:
an inner portion;
an intermediate portion;
an outer portion;
two first torsion webs spanning between the inner portion and the intermediate portion; and
two second torsion webs spanning between the intermediate portion and the outer portion, in which, for each first biaxial flexure bearing:
the inner portion thereof is interposed between the two first torsion webs thereof, and
the intermediate portion thereof is interposed between the two second torsion webs thereof.

Implementation 7: The apparatus of implementation 6, in which, for each first biaxial flexure bearing:
the first torsion webs thereof are thin, substantially planar structures aligned with a first reference plane of that first biaxial flexure bearing,
the second torsion webs thereof are thin, substantially planar structures aligned with a second reference plane of that first biaxial flexure bearing, and
the first and second reference planes thereof are perpendicular to one another.

Implementation 8: The apparatus of implementation 6 or implementation 7, in which:
the intermediate portion includes two opposing first segments arranged on opposite sides of the inner portion and first torsion webs and spaced apart from the inner portion such that gaps exist between the first segments and the inner portion,
the intermediate portion further includes two opposing second segments arranged on opposite sides of the inner portion and spaced apart from the inner portion such that gaps exist between the second segments and the inner portion,
each second segment is connected with the inner portion by a corresponding one of the second torsion webs,
the intermediate portion further includes four bridging segments, each bridging segment extending between a different pair of the first and second segments, and
the second segments are further from a center axis of the inner portion than are the first segments.

Implementation 9: The apparatus of implementation 8, in which the first segments are curved segments having convex surfaces facing towards the inner portion.

Implementation 10: The apparatus of implementation 9, in which the first segments are arcuate segments that are concentric with the inner portion.

Implementation 11: The apparatus of any one of implementations 8 through 10, in which the bridging segments are linear segments.

Implementation 12: The apparatus of implementation 11, in which the bridging segments are parallel to one another.

Implementation 13: The apparatus of any one of implementations 8 through 12, in which the second segments are located entirely outside of a reference circle that circumscribes the first segments.

Implementation 14: The apparatus of any one of implementations 8 through 13, in which the distances between the inner portion and the second segments are at least 1.5 times the distances between the inner portion and the first segments.

Implementation 15: The apparatus of any one of implementations 8 through 13, in which the distances between the inner portion and the second segments are at least twice as large as the distances between the inner portion and the first segments.

Implementation 16: The apparatus of any one of implementations 7 through 15, in which, for each first biaxial flexure bearing, a first reference axis defined by the intersection of the first and second reference planes is parallel to an extension axis of the linear actuator connected to that first biaxial flexure bearing.

Implementation 17: The apparatus of implementation 5, in which each first biaxial flexure bearing includes:
a first portion;
a second portion;
a third portion;
two first bending webs spanning between the first portion and the second portion; and
two second bending webs spanning between the second portion and the third portion, in which, for each first biaxial flexure bearing:
the second portion thereof is interposed between the first portion thereof and the third portion thereof,
the first portion thereof, the second portion thereof, and the third portion thereof lie along a common axis thereof,
a first gap exists between the first portion thereof and the second portion thereof, and
a second gap exists between the second portion thereof and the third portion thereof.

Implementation 18: The apparatus of implementation 17, in which, for each first biaxial flexure bearing:
the first bending webs thereof are thin, substantially planar structures aligned with a first reference plane of that first biaxial flexure bearing,
the second bending webs thereof are thin, substantially planar structures aligned with a second reference plane of that first biaxial flexure bearing, and
the first and second reference planes thereof are perpendicular to one another.

Implementation 19: The apparatus of implementation 17 or implementation 18, in which each first biaxial flexure bearing includes a center hole that extends along the common axis of that first biaxial flexure bearing and through the first portion thereof, the second portion thereof, and the third portion thereof.

Implementation 20: The apparatus of any one of implementations 17 through 19, in which, for each first biaxial flexure bearing:
that first biaxial flexure bearing includes two first through-holes and two second through-holes,
the first bending webs thereof are positioned in between the first through-holes thereof,
the second bending webs thereof are positioned in between the second through-holes thereof,
the first through-holes thereof extend completely through that first biaxial flexure bearing, and
the second through-holes thereof extend completely through that first biaxial flexure bearing.

Implementation 21: The apparatus of any one of implementations 17 through 20, in which the first bending webs and the second bending webs of each first biaxial flexure bearing extend into the second portion thereof.

Implementation 22: The apparatus of any one of implementations 1 through 16, in which each second end of each linear actuator is pivotably connected with the movable mount by a corresponding second biaxial flexure bearing.

Implementation 23: The apparatus of implementation 22, in which each second biaxial flexure bearing includes:
an inner portion;
an intermediate portion;
an outer portion;
two first torsion webs spanning between the inner portion and the intermediate portion; and
two second torsion webs spanning between the intermediate portion and the outer portion, in which, for each first biaxial flexure bearing:
the inner portion thereof is interposed between the two first torsion webs thereof, and
the intermediate portion thereof is interposed between the two second torsion webs thereof.

Implementation 24: The apparatus of implementation 23, in which, for each second biaxial flexure bearing:
the first torsion webs thereof are thin, substantially planar structures aligned with a first reference plane of that second biaxial flexure bearing,
the second torsion webs thereof are thin, substantially planar structures aligned with a second reference plane of that second biaxial flexure bearing, and
the first and second reference planes thereof are perpendicular to one another.

Implementation 25: The apparatus of implementation 24, in which, for each second biaxial flexure bearing:
the first and second reference planes intersect along a center axis thereof, and
the center axis thereof is parallel to an extension axis of the linear actuator connected thereto.

Implementation 26: The apparatus of any one of implementations 1 through 25, further including a semiconductor processing chamber and a showerhead, in which:
the wafer support surface of the pedestal is located within the semiconductor processing chamber,
at least a portion of the showerhead is located within the semiconductor processing chamber, and
the stationary mount is fixed with respect to the semiconductor processing chamber.

Implementation 27: The apparatus of implementation 26, further including a controller, the controller operatively connected with the six linear actuators and configured to control the linear actuators so as to cause the movable mount to perform, relative to the stationary mount, one or more of: a) translation of the movable mount along an axis that is perpendicular to the wafer support surface of the pedestal, b) rotation of the movable mount about a rotational axis that passes through a target location of the pedestal on which a wafer is to be centered and is perpendicular to the wafer support surface, c) translation of the movable mount along a path so as to orbit an axis that is perpendicular to an underside of the showerhead that faces towards the pedestal and that intersects with a target location of the showerhead, d) tilting of the movable mount such that the wafer support surface of the pedestal is oriented at a non-zero acute angle to the underside of the showerhead, or e) tilting of the movable mount such that the wafer support surface of the pedestal is oriented at a non-zero acute angle to the underside of the showerhead and such that a maximum acute angle that is formed between the underside of the showerhead and the wafer support surface is defined in a plane that is periodically or continuously caused to change azimuthal direction relative to the pedestal and about an axis that is perpendicular to the underside of the showerhead.

Implementation 28: The apparatus of implementation 27, in which the controller is further configured to control the linear actuators so as to cause the movable mount to perform two or more of (a) through (e) at least partially simultaneously while the pedestal is supporting a wafer placed thereupon.

Implementation 29: The apparatus of either implementation 27 or implementation 28, in which the controller is further configured to control the linear actuators so as to cause the movable mount to perform two or more of (a) through (e) at least partially sequentially while the pedestal is supporting a wafer placed thereupon.

Implementation 30: The apparatus of any one of implementations 27 through 29, further including:
a wafer handling robot configured to extend an end effector thereof into the semiconductor processing chamber; and
an active wafer centering system configured to determine a location of a center of a wafer transported by the end effector relative to the semiconductor processing chamber, in which:
the controller is further configured to:
i) obtain the location of the center of the wafer as determined by the active wafer centering system,
ii) control the linear actuators so as to cause the target location of the pedestal to be positioned at a location centered beneath the center of the wafer based on the location of the center of the wafer as determined by the active wafer centering system, and
iii) cause the wafer to be transferred to the pedestal after (ii).

Implementation 31: The apparatus of implementation 30, in which:
the pedestal includes a plurality of lift pins and the apparatus includes a lift pin actuation mechanism that is configured to move the lift pins between an extended state in which the lift pins protrude from the wafer support surface of the pedestal and a retracted state in which the lift pins do not protrude from the wafer support surface, and
the controller is configured to perform (iii) by causing the lift pin actuation mechanism to cause the lift pins to move into the extended state so as to come into contact with the wafer, causing the wafer handling robot to retract the end effector from the space between the wafer and the wafer support surface, and causing the lift pin actuation mechanism to cause the lift pins to move into the retracted state, thereby placing the wafer on the wafer support surface.

Implementation 32: The apparatus of either implementation 30 or implementation 31, in which the controller is further configured to, after (iii), control the linear actuators so as to cause the movable mount to move to an orientation in which the wafer support surface is at a predetermined angle relative to the underside of the showerhead.

Implementation 33: The apparatus of implementation 32, in which the predetermined angle is 0°.

Implementation 34: The apparatus of implementation 32, in which the predetermined angle is a non-zero acute angle.

1. An apparatus comprising:
a pedestal configured to support a semiconductor wafer during wafer processing operations;
a hexapod mechanism that includes:
a movable mount that supports the pedestal;
a stationary mount; and
six independently controllable linear actuators, each linear actuator having a first end pivotably connected with the stationary mount and a second end pivotably connected with the movable mount, wherein the linear actuators support the movable mount relative to the stationary mount.

2. The apparatus of claim 1, wherein the linear actuators are arranged in a trilaterally symmetric manner.

3. The apparatus of claim 1, wherein:
the six linear actuators are grouped into three sets of two linear actuators, and
the linear actuators in each set of two linear actuators are arranged so as to have first ends that connect with the stationary mount at locations that are closer together than locations where the second sends thereof connect with the movable mount.

4. The apparatus of claim 1, wherein:
each first end of each linear actuator is pivotably connected with the stationary mount by a corresponding spherical joint, universal joint, or biaxial flexure bearing, and
each second end of each linear actuator is pivotably connected with the movable mount by a corresponding spherical joint, universal joint, or biaxial flexure bearing.

5. The apparatus of claim 1, wherein each first end of each linear actuator is pivotably connected with the stationary mount by a corresponding first biaxial flexure bearing.

6. The apparatus of claim 5, wherein each first biaxial flexure bearing includes:
a first portion;
a second portion;
a third portion;
two first bending webs spanning between the first portion and the second portion; and
two second bending webs spanning between the second portion and the third portion, wherein, for each first biaxial flexure bearing:
the second portion thereof is interposed between the first portion thereof and the third portion thereof,
the first portion thereof, the second portion thereof, and the third portion thereof lie along a common axis thereof,
a first gap exists between the first portion thereof and the second portion thereof, and
a second gap exists between the second portion thereof and the third portion thereof.

7. The apparatus of claim 6, wherein, for each first biaxial flexure bearing:
the first bending webs thereof are thin, substantially planar structures aligned with a first reference plane of that first biaxial flexure bearing,
the second bending webs thereof are thin, substantially planar structures aligned with a second reference plane of that first biaxial flexure bearing, and
the first and second reference planes thereof are perpendicular to one another.

8. The apparatus of claim 6, wherein each first biaxial flexure bearing includes a center hole that extends along the common axis of that first biaxial flexure bearing and through the first portion thereof, the second portion thereof, and the third portion thereof.

9. The apparatus of claim 6, wherein, for each first biaxial flexure bearing:
that first biaxial flexure bearing includes two first through-holes and two second through-holes,
the first bending webs thereof are positioned in between the first through-holes thereof,
the second bending webs thereof are positioned in between the second through-holes thereof,
the first through-holes thereof extend completely through that first biaxial flexure bearing, and
the second through-holes thereof extend completely through that first biaxial flexure bearing.

10. The apparatus of claim 6, wherein the first bending webs and the second bending webs of each first biaxial flexure bearing extend into the second portion thereof.

11. The apparatus of claim 1, further comprising a semiconductor processing chamber and a showerhead, wherein:
the wafer support surface of the pedestal is located within the semiconductor processing chamber,
at least a portion of the showerhead is located within the semiconductor processing chamber, and
the stationary mount is fixed with respect to the semiconductor processing chamber.

12. The apparatus of claim 11, further comprising a controller, the controller operatively connected with the six linear actuators and configured to control the linear actuators so as to cause the movable mount to perform, relative to the stationary mount, one or more of: a) translation of the movable mount along an axis that is perpendicular to the wafer support surface of the pedestal, b) rotation of the movable mount about a rotational axis that passes through a target location of the pedestal on which a wafer is to be centered and is perpendicular to the wafer support surface, c) translation of the movable mount along a path so as to orbit an axis that is perpendicular to an underside of the showerhead that faces towards the pedestal and that intersects with a target location of the showerhead, d) tilting of the movable mount such that the wafer support surface of the pedestal is oriented at a non-zero acute angle to the underside of the showerhead, or e) tilting of the movable mount such that the wafer support surface of the pedestal is oriented at a non-zero acute angle to the underside of the showerhead and such that a maximum acute angle that is formed between the underside of the showerhead and the wafer support surface is defined in a plane that is periodically or continuously caused to change azimuthal direction relative to the pedestal and about an axis that is perpendicular to the underside of the showerhead.

13. The apparatus of claim 12, wherein the controller is further configured to control the linear actuators so as to cause the movable mount to perform two or more of (a) through (e) at least partially simultaneously while the pedestal is supporting a wafer placed thereupon.

14. The apparatus of claim 12, wherein the controller is further configured to control the linear actuators so as to cause the movable mount to perform two or more of (a) through (e) at least partially sequentially while the pedestal is supporting a wafer placed thereupon.

15. The apparatus of claim 12, further comprising:
a wafer handling robot configured to extend an end effector thereof into the semiconductor processing chamber; and
an active wafer centering system configured to determine a location of a center of a wafer transported by the end effector relative to the semiconductor processing chamber, wherein:
the controller is further configured to:
i) obtain the location of the center of the wafer as determined by the active wafer centering system,
ii) control the linear actuators so as to cause the target location of the pedestal to be positioned at a location centered beneath the center of the wafer based on the location of the center of the wafer as determined by the active wafer centering system, and
iii) cause the wafer to be transferred to the pedestal after (ii).

16. The apparatus of claim 15, wherein:
the pedestal includes a plurality of lift pins and the apparatus includes a lift pin actuation mechanism that is configured to move the lift pins between an extended state in which the lift pins protrude from the wafer support surface of the pedestal and a retracted state in which the lift pins do not protrude from the wafer support surface, and
the controller is configured to perform (iii) by causing the lift pin actuation mechanism to cause the lift pins to move into the extended state so as to come into contact with the wafer, causing the wafer handling robot to retract the end effector from the space between the wafer and the wafer support surface, and causing the lift pin actuation mechanism to cause the lift pins to move into the retracted state, thereby placing the wafer on the wafer support surface.

17. The apparatus of claim 15, wherein the controller is further configured to, after (iii), control the linear actuators so as to cause the movable mount to move to an orientation in which the wafer support surface is at a predetermined angle relative to the underside of the showerhead.

18. The apparatus of claim 17, wherein the predetermined angle is 0°.

19. The apparatus of claim 17, wherein the predetermined angle is a non-zero acute angle.
